(19) United States
(12) Patent Application Publication
(10) Pub. No.: US 2026/0173589 A1
(43) Pub. Date: Jun. 18, 2026

(54) DISPLAY PANEL AND DISPLAY DEVICE

(71) Applicants: HEFEI VISIONOX ELECTRONICS CO., LTD., Hefei (CN); VISIONOX TECHNOLOGY INC., Jiangsu (CN)

(72) Inventors: Yuan YAO, Hefei (CN); Aihua XUE, Hefei (CN); Chaoran QIN, Hefei (CN)

(73) Assignees: HEFEI VISIONOX ELECTRONICS CO., LTD., Hefei (CN); VISIONOX TECHNOLOGY INC., Jiangsu (CN)

(21) Appl. No.: 19/426,246

(22) Filed: Dec. 19, 2025

Related U.S. Application Data
(63) Continuation of application No. PCT/CN2025/131377, filed on Oct. 30, 2025.

(30) Foreign Application Priority Data
Dec. 13, 2024 (CN) 202411846884.2

(51) Int. Cl. H10H 20/819; H10H 20/853; H10H 29/37

(52) U.S. Cl. CPC H10H 20/819; H10H 20/853; H10H 29/37

(57) ABSTRACT

A display panel and a display device. The display panel includes a substrate, a first electrode layer, an isolation structure, and a light-emitting functional layer. The first electrode layer is disposed on a side of the substrate and includes a plurality of first electrodes spaced apart. The isolation structure is disposed on a side of the substrate and is provided with a plurality of isolation openings. An orthographic projection of a first electrode on the substrate overlaps an orthographic projection of an isolation opening on the substrate. The light-emitting functional layer is disposed on a side of the first electrode layer away from the substrate and includes a light-emitting structure disposed corresponding to the first electrode.

### CROSS-REFERENCE TO RELATED APPLICATION

The present application is a continuation of International Application No. PCT/CN2025/131377 filed on Oct. 30, 2025, which claims priority to Chinese Patent Application No. 202411846884.2 filed on Dec. 13, 2024, and titled “DISPLAY PANEL AND DISPLAY DEVICE”, both of which are hereby incorporated by reference in their entireties.

### TECHNICAL FIELD

The present application relates to the technology field of display devices, and in particular, to a display panel and a display device.

### BACKGROUND

Flat display panels such as Organic Light Emitting Diode (OLED) panels and display panels utilizing Light Emitting Diode (LED) devices are widely used in various consumer electronic products such as mobile phones, televisions, personal digital assistants, digital cameras, notebook computers, and desktop computers due to their advantages of high image quality, low power consumption, thin profile, and wide application range, and have become mainstream in display devices.

### SUMMARY

Embodiments of the present application provide a display panel and a display device, which can improve the reliability of the display panel.

In a first aspect, an embodiment of the present application provides a display panel, including:
a substrate;
a first electrode layer disposed on a side of the substrate, the first electrode layer including a plurality of first electrodes spaced apart;
an isolation structure disposed on a side of the substrate, the isolation structure being provided with a plurality of isolation openings, an orthographic projection of a first electrode on the substrate overlapping an orthographic projection of an isolation opening on the substrate;
a light-emitting functional layer disposed on a side of the first electrode layer away from the substrate, the light-emitting functional layer including a light-emitting structure disposed corresponding to the first electrode;
wherein the isolation structure has a first orthographic projection on the substrate, the first orthographic projection defines a plurality of first opening patterns, the first electrode has a second orthographic projection on the substrate, a first opening pattern overlaps the second orthographic projection, and at least a part of a graphic outer contour shape of the second orthographic projection is the same as an outer contour shape of the first opening pattern.

In a second aspect, an embodiment of the present application provides a display panel, including:
a substrate;
a first electrode layer disposed on a side of the substrate, the first electrode layer including a plurality of first electrodes spaced apart;
an isolation structure disposed on a side of the substrate, the isolation structure being provided with a plurality of isolation openings, an orthographic projection of a first electrode on the substrate overlapping an orthographic projection of an isolation opening on the substrate;
a light-emitting functional layer disposed on a side of the first electrode layer away from the substrate, the light-emitting functional layer including a light-emitting structure disposed corresponding to the first electrode;
wherein the isolation structure has a first orthographic projection on the substrate, the first orthographic projection defines a plurality of first opening patterns, the first electrode has a second orthographic projection on the substrate, the second orthographic projection includes a first straight edge, the first opening pattern includes a second straight edge, and the first straight edge is parallel to the second straight edge.

In a third aspect, an embodiment of the present application provides a display panel, including:
a substrate;
an isolation structure disposed on a side of the substrate, the isolation structure being provided with a plurality of isolation openings;
a light-emitting functional layer disposed on a side of the substrate, the light-emitting functional layer including a light-emitting structure at least partially located within an isolation opening;
wherein the isolation structure has a first orthographic projection on the substrate, the first orthographic projection defines a plurality of first opening patterns, the plurality of first opening patterns include a first sub-opening, a second sub-opening, and a third sub-opening, the first sub-opening, the second sub-opening, and the third sub-opening respectively correspond to light-emitting structures of different colors;
centers of at least two first sub-openings and centers of at least two second sub-openings form a first virtual polygon, the centers of the first sub-openings are located at first vertexes of the first virtual polygon, the centers of the second sub-openings are located at second vertexes of the first virtual polygon, the first vertices and the second vertices are alternately arranged in the first virtual polygon, the third sub-opening is located inside the first virtual polygon.

The embodiments of the present application provide a display panel and a display device. The morphology, size, and shape of the first electrode are adjusted, which helps to reduce the overall size of the first electrode and reduce the overlapping area between the first orthographic projection and the second orthographic projection, this design can reduce the parasitic capacitance between them, improve the reliability of signal transmission of the isolation structure and the first electrode, and enhance the display reliability of the display panel.

### BRIEF DESCRIPTION OF THE DRAWINGS

In order to more clearly illustrate the technical solutions of the embodiments of the present application, the drawings required for describing the embodiments of the present application will be briefly introduced below. It will be apparent to those skilled in the art that other drawings can be obtained from these drawings without creative effort.

FIG. 1 is a partial schematic structural diagram of a display panel according to an embodiment of the present application;

FIG. 2 is a partial schematic structural diagram of an isolation structure in a display panel according to an embodiment of the present application;

FIG. 3 is a partial schematic structural diagram of a first electrode layer in a display panel according to an embodiment of the present application;

FIG. 4 is a cross-sectional structural diagram at A-A in FIG. 1;

FIG. 5 is a partial schematic structural diagram of a first isolation portion in a display panel according to an embodiment of the present application;

FIG. 6 is a schematic diagram showing the relative positional relationship between a first electrode layer and a first isolation portion in a display panel according to an embodiment of the present application;

FIG. 7 is a schematic diagram showing the relative positional relationship between a second isolation portion and a light-emitting functional layer in a display panel according to an embodiment of the present application;

FIG. 8 is a partial schematic structural diagram of an isolation structure in another display panel according to an embodiment of the present application;

FIG. 9 is a partial schematic structural diagram of an isolation structure in yet another display panel according to an embodiment of the present application;

FIG. 10 is a schematic diagram showing the positional relationship between an isolation structure and a first electrode layer in yet another display panel according to an embodiment of the present application;

FIG. 11 is a schematic diagram showing the positional relationship between a first conductor layer and a first electrode layer in yet another display panel according to an embodiment of the present application;

FIG. 12 is a schematic diagram showing the positional relationship between a first conductor layer and a first electrode layer in yet another display panel according to an embodiment of the present application;

FIG. 13 is a schematic diagram showing the positional relationship between a first conductor layer and a first electrode layer in yet another display panel according to an embodiment of the present application;

FIG. 14 is a cross-sectional structural diagram of yet another display panel according to an embodiment of the present application.

### DETAILED DESCRIPTION

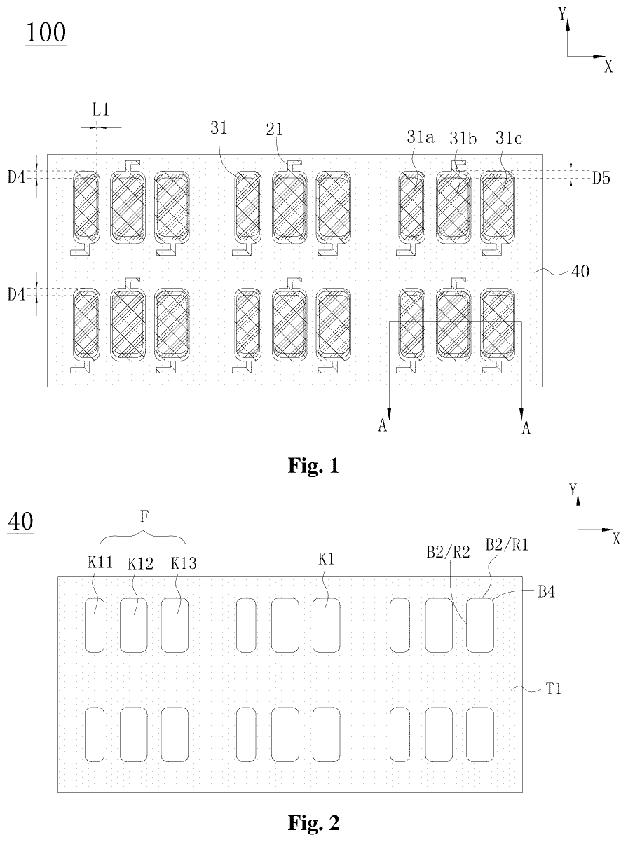

In a first aspect, referring to FIGS. 1 to 4, an embodiment of the present application provides a display panel 100. The display panel 100 includes a substrate 10, a first electrode layer 20, an isolation structure 40, and a light-emitting functional layer 30. The first electrode layer 20 is disposed on a side of the substrate 10 and includes a plurality of first electrodes 21 spaced apart. The isolation structure 40 is disposed on a side of the substrate 10 and is provided with a plurality of isolation openings 41. An orthographic projection of a first electrode 21 on the substrate 10 overlaps an orthographic projection of an isolation opening 41 on the substrate 10. The light-emitting functional layer 30 is disposed on a side of the first electrode layer 20 away from the substrate 10 and includes a light-emitting structure 31 disposed corresponding to the first electrode 21.

The isolation structure 40 has a first orthographic projection T1 on the substrate 10. The first orthographic projection T1 defines a plurality of first opening patterns K1. The first electrode 21 has a second orthographic projection T2 on the substrate 10. The first opening pattern K1 overlaps the second orthographic projection T2, and at least a part of a graphic outer contour shape of the second orthographic projection T2 is the same as an outer contour shape of the first opening pattern K1. It should be noted that if the two outer contour shapes are basically the same, they can also be regarded as having the same outer contour shape.

The substrate 10 is a structure in the display panel 100 for carrying other film layers. The substrate 10 includes a plurality of film layer structures. The specific composition of the film layer structures inside the substrate 10 is not limited in the embodiments of the present application. The plurality of film layer structures inside the substrate 10 and the plurality of film layer structures outside the substrate 10 are all stacked along the thickness direction Z of the substrate 10. The thickness direction Z of different film layer structures, the thickness direction Z of the display panel 100, and the thickness direction Z of the substrate 10 are usually parallel. Therefore, for ease of understanding, the thickness direction Z of different film layer structures, the thickness direction Z of the display panel 100, and the thickness direction Z of the substrate 10 are all indicated by the same direction in the drawings.

The first electrode layer 20 and the light-emitting functional layer 30 are disposed on the same side of the substrate 10 along the thickness direction Z, and the light-emitting functional layer 30 is located on the side of the first electrode layer 20 away from the substrate 10 along the thickness direction Z. The light-emitting functional layer 30 is a functional film layer in the display panel 100 for achieving the display effect, and the first electrode layer 20 is an electrode film layer for controlling whether the light-emitting functional layer 30 emits light. Optionally, the display panel 100 further includes a second electrode layer 50 located on the side of the light-emitting functional layer 30 away from the substrate 10. The first electrode layer 20 and the second electrode layer 50 cooperate with each other to control whether the light-emitting functional layer 30 emits light. Exemplarily, the first electrode layer 20 is an anode layer, and the second electrode layer 50 is a cathode layer.

The first electrode layer 20 includes a plurality of first electrodes 21 spaced apart. The light-emitting functional layer 30 includes a light-emitting structure 31 disposed corresponding to the first electrode 21. The phrase “a light-emitting structure 31 disposed corresponding to the first electrode 21” mentioned here means that the orthographic projection of each light-emitting structure 31 on the substrate 10 can overlap the orthographic projection of one first electrode 21 on the substrate 10. Depending on actual needs, a single first electrode 21 may correspond to only a single light-emitting structure 31, that is, a single first electrode 21 is only used to control a single light-emitting structure 31; or a single first electrode 21 may correspond to a plurality of light-emitting structures 31, that is, a single first electrode 21 can also be used to control the plurality of light-emitting structures 31. For ease of understanding, the subsequent description in the embodiments of the present application will use the example where a single first electrode 21 corresponds to only a single light-emitting structure 31.

The light-emitting structure 31 includes, but is not limited to, a red light-emitting structure 31 for emitting red light, a green light-emitting structure 31 for emitting green light, and a blue light-emitting structure 31 for emitting blue light. Each light-emitting structure 31 may include stacked film layers such as a Hole Inject Layer (HIL), a Hole Transport Layer (HTL), a light-emitting layer, an Electron Inject Layer (EIL), and an Electron Transport Layer (ETL). In some other embodiments, the light-emitting structure 31 may include a plurality of light-emitting layers stacked, and a charge generation layer is provided between adjacent light-emitting layers.

The isolation structure 40 is a structure in the display panel 100 for separating different light-emitting structures 31. The isolation structure 40 encloses and forms a plurality of isolation openings 41. The plurality of isolation openings 41 respectively correspond to the plurality of light-emitting structures 31 and the plurality of first electrodes 21. That is, the orthographic projection of a single isolation opening 41 on the substrate 10 can overlap the orthographic projection of a single light-emitting structure 31 on the substrate 10, and at the same time, can also overlap the orthographic projection of a single first electrode 21 on the substrate 10.

The provision of the isolation structure 40 allows the light-emitting functional layer 30 to form a plurality of light-emitting structures 31 spaced apart without the need for a fine metal mask, thereby reducing the manufacturing cost of the display panel 100. Specifically, taking the red light-emitting structure 31 being prepared before the green light-emitting structure 31 as an example, since the fine metal mask is eliminated, the red light-emitting material corresponding to the red light-emitting structure 31 first falls into each isolation opening 41. Then, the red light-emitting material in a part of the isolation openings 41 is selectively etched away, and the red light-emitting material in the remaining part of the isolation openings 41 is retained to form the red light-emitting structure 31. After that, the green light-emitting material corresponding to the green light-emitting structure 31 falls into each isolation opening 41. Then, the green light-emitting material in a part of the isolation openings 41 is selectively etched away, and the green light-emitting material in the remaining part of the isolation openings 41 is retained to form the green light-emitting structure 31.

The first orthographic projection T1 is the orthographic projection of the isolation structure 40 on the substrate 10. Due to the presence of the isolation openings 41, the first orthographic projection T1 can define a plurality of first opening patterns K1. Considering that the cross-sectional area of the isolation structure 40 at different positions in the thickness direction Z may not be completely consistent, the first orthographic projection T1 is the orthographic projection corresponding to the position where the isolation structure 40 has the maximum cross-sectional area, and the first opening pattern K1 is the opening pattern defined and surrounded by the first orthographic projection T1.

Similarly, similar as the isolation structure 40, the radial dimension of the isolation opening 41 at different positions in the thickness direction Z is not completely consistent. Therefore, the orthographic projection of the isolation opening 41 on the substrate 10 is the orthographic projection corresponding to the position where the isolation opening 41 has the maximum radial dimension. The position where the isolation opening 41 has the maximum radial dimension is usually aligned with the position where the isolation structure 40 has the minimum cross-sectional area. Thus, it can be seen that the first opening pattern K1 is not the orthographic projection of the isolation opening 41 on the substrate 10. Referring to FIG. 4, the orthographic projection of the virtual line I1 on the substrate can coincide with the outer contour of the first opening pattern K1, and the orthographic projection of the virtual line I2 on the substrate can coincide with the outer contour of the orthographic projection of the isolation opening 41 on the substrate 10. Further optionally, the graphic outer contour shape of the orthographic projection of the isolation opening 41 on the substrate 10 may be the same as the outer contour shape of the first opening pattern K1.

It should be noted that the “radial dimension” mentioned here refers to a dimension in a direction parallel to the plane of the substrate 10 at a specific position of the isolation opening 41. It does not limit the shape of the isolation opening 41. The orthographic projection of the isolation opening 41 on the substrate 10 and the first opening pattern K1 may be a circular shape, a polygonal shape, or other regular or irregular shapes, which is not limited in the embodiments of the present application.

The second orthographic projection T2 is the orthographic projection of the first electrode 21 on the substrate 10. The second orthographic projection T2 overlaps the first opening pattern K1. The orthographic projection of the light-emitting structure 31 on the substrate 10 also overlaps the first opening pattern K1. However, the specific positional relationship between the first orthographic projection T1 and the second orthographic projection T2 is not limited in the embodiments of the present application. For example, the first orthographic projection T1 and the second orthographic projection T2 may overlap, the end of the first electrode 21 is located below the isolation structure 40 and is insulated from the isolation structure 40. Alternatively, the second orthographic projection T2 may be located outside the first orthographic projection T1.

In related technologies, the display panel 100 often does not include an isolation structure 40, and a relatively large-sized anode structure needs to be provided to cover and shield a part of the conductor structure or the semiconductor structure inside the substrate 10, thereby reducing adverse effects caused by light shining on the conductor structure or the semiconductor structure.

However, in the embodiment of the present application, considering the presence of the isolation structure 40, if the size and morphology of the first electrode 21 are still set similar to those in the related art, the display performance of the display panel will be affected. For example, it may cause the first orthographic projection T1 and the second orthographic projection T2 to overlap and produce a large overlapping area. Further, since at least a part of the structure in the isolation structure 40 can be set to include conductive material, that is, at least a part of the structure in the isolation structure 40 can be a conductor structure or a semiconductor structure. Therefore, this design is likely to cause a large parasitic capacitance between the isolation structure 40 and the first electrode 21, and create a risk of signal crosstalk, affecting the reliability of signal transmission of the isolation structure 40 and the first electrode 21, and thus easily adversely affecting the display image.

In view of this, the embodiment of the present application adjusts the morphology, size, and shape of the first electrode 21. By changing the morphology of the first electrode 21, at least a part of the graphic outer contour shape of the second orthographic projection T2 is set to be the same as the outer contour shape of the first opening pattern K1, this helps to reduce the overall size of the first electrode 21 and reduce the overlapping area between the first orthographic projection T1 and the second orthographic projection T2, and this design can reduce the parasitic capacitance between them, improve the reliability of signal transmission of the isolation structure 40 and the first electrode 21, and enhance the display reliability of the display panel 100.

Furthermore, since the isolation structure 40 can also cover and shield a part of the conductor structure or the semiconductor structure inside the substrate 10, the adverse effects of factors such as light exposure on the display effect can be reduced. Therefore, even if the size of the first electrode 21 is reduced in the embodiment of the present application, it will not affect the performance reliability of the conductor structure or the semiconductor structure inside the substrate 10, thereby helping to further improve the use reliability of the display panel 100.

In some optional embodiments, the display panel 100 includes a thin film transistor J. The orthographic projection of the isolation structure 40 on the substrate 10 overlaps the thin film transistor J. In this way, the isolation structure 40 can serve as a light shield for the thin film transistor J, thereby reducing the impact of light.

It should be noted that the “same” mentioned here means that the outer contour shapes are substantially the same, and does not require complete consistency. The “same” mentioned later in the present application is similar, and will not be repeated later in the present application. Moreover, for the second orthographic projection T2, the graphic outer contour shape corresponding to the second orthographic projection T2 may be the same or substantially the same as the outer contour shape of the first opening pattern K1, or according to actual needs, a part of the graphic outer contour shape of the second orthographic projection T2 may also be different from the outer contour shape of the first opening pattern K1, which is not limited in the embodiments of the present application, as long as at least a part of the graphic outer contour shape of the second orthographic projection T2 is the same as the outer contour shape of the first opening pattern K1.

In some embodiments, as shown in FIG. 4, the isolation structure 40 includes a first isolation portion 42 and a second isolation portion 43 located on a side of the first isolation portion 42 away from the substrate 10. The orthographic projection of the first isolation portion 42 on the substrate 10 is located within the orthographic projection of the second isolation portion 43 on the substrate 10.

The specific size and shape of the first isolation portion 42 and the second isolation portion 43 are not limited in the embodiment of the present application. For example, the longitudinal section of the isolation structure 40 may be T-shaped, or the longitudinal section of the isolation structure 40 may be an inverted trapezoid. This design helps to prevent the light-emitting material from easily extending along the sidewall of the first isolation portion 42 to the sidewall of the second isolation portion 43 during the preparation of the light-emitting functional layer 30, thereby achieving the preparation and separation of the light-emitting structures 31 corresponding to different isolation openings 41 without the need for the fine metal mask.

The material composition of the first isolation portion 42 and the second isolation portion 43 is not limited in the embodiment of the present application. The first isolation portion 42 and the second isolation portion 43 may both include conductive material, or the first isolation portion 42 includes conductive material and the second isolation portion 43 includes insulating material, or the first isolation portion 42 and the second isolation portion 43 may both include insulating material.

In some embodiments, referring to FIGS. 1 to 5, the first isolation portion 42 has a third orthographic projection T3 on the substrate 10. The third orthographic projection T3 defines a plurality of second opening patterns K2. At least a part of the graphic outer contour shape of the second orthographic projection T2 is the same as the outer contour shape of the second opening pattern K2.

The third orthographic projection T3 is the orthographic projection of the first isolation portion 42 on the substrate 10. The third orthographic projection T3 can define a plurality of second opening patterns K2. Considering that the cross-sectional area of the first isolation portion 42 at different positions in the thickness direction Z may not be completely consistent, the third orthographic projection T3 is the orthographic projection corresponding to the position where the first isolation portion 42 has the maximum cross-sectional area, and the second opening pattern K2 is the opening pattern defined and surrounded by the third orthographic projection T3.

The second orthographic projection T2 is the orthographic projection of the first electrode 21 on the substrate 10. The second orthographic projection T2 overlaps the second opening pattern K2. Similarly, the orthographic projection of the light-emitting structure 31 on the substrate 10 also overlaps the second opening pattern K2. The specific positional relationship between the second orthographic projection T2 and the third orthographic projection T3 is not limited in the embodiment of the present application. For example, the second orthographic projection T2 and the third orthographic projection T3 may overlap, or the second orthographic projection T2 may be located outside the third orthographic projection T3.

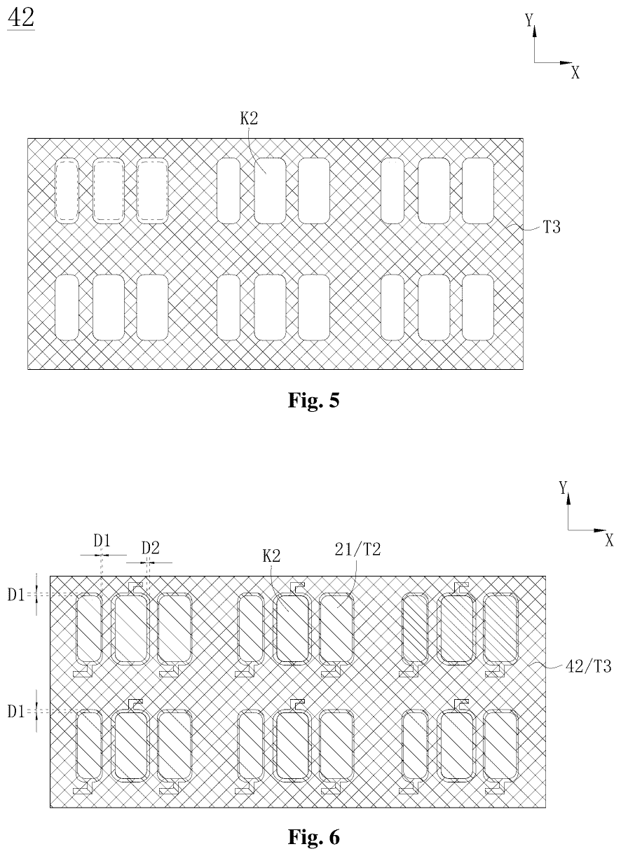

For the first opening pattern K1 and the second opening pattern K2, since the orthographic projection of the first isolation portion 42 on the substrate 10 is located within the orthographic projection of the second isolation portion 43 on the substrate 10, the orthographic projection of the first isolation portion 42 on the substrate 10 will not coincide with the orthographic projection of the isolation structure 40 on the substrate 10, that is, the first orthographic projection T1 will not coincide with the third orthographic projection T3. Thus, the first opening pattern K1 and the second opening pattern K2 will not completely coincide. Optionally, the first opening pattern K1 is located within the second opening pattern K2, and the edge of the first opening pattern K1 is spaced apart from the edge of the second opening pattern K2. In FIG. 5, the outer contour of the first opening pattern K1 is indicated by a dashed line.

Further, in the embodiment of the present application, similar to the first opening pattern K1, at least a part of the graphic outer contour shape of the second orthographic projection T2 is also the same as the outer contour shape of the second opening pattern K2, thus through this conformal design between them, the shape matching degree between the first electrode 21 and the light-emitting structure 31 can be further improved, and the display reliability of the display panel 100 can be improved.

In some optional embodiments, as shown in FIG. 4, the display panel 100 further includes a second electrode layer 50 disposed on a side of the light-emitting functional layer 30 away from the substrate 10. The second electrode layer 50 includes a second electrode 51 disposed corresponding to the isolation opening 41. The first isolation portion 42 includes conductive material. The second electrode 51 is in contact with and electrically connected to the sidewall of the first isolation portion 42.

The phrase “a second electrode 51 disposed corresponding to the isolation opening 41” mentioned here means that the orthographic projection of the second electrode 51 on the substrate 10 overlaps the orthographic projection of the isolation opening 41 on the substrate 10. Further, the orthographic projection of the second electrode 51 on the substrate 10 overlaps the first opening pattern K1.

The first isolation portion 42 includes conductive material and is used to transmit a corresponding power signal to the second electrode 51. On this basis, in order to reduce the parasitic capacitance between the first isolation portion 42 and the first electrode 21, at least a part of the graphic outer contour shape of the second orthographic projection T2 is set to be the same as the outer contour shape of the second opening pattern K2 in the embodiment of the present application, thus through this conformal design between them, the overlapping area between the second orthographic projection T2 and the third orthographic projection T3 can be reduced, thereby reducing the parasitic capacitance between them and improving the display effect.

In some embodiments, as shown in FIG. 4, in a direction perpendicular to the display panel 100 and away from the substrate 10, the dimension of the first isolation portion 42 in a first direction X gradually decreases. The first direction X is parallel to the plane of the substrate 10.

The direction perpendicular to the display panel 100 is the thickness direction Z. The first direction X is a direction intersecting the thickness direction Z. Optionally, the first direction X is perpendicular to the thickness direction Z. In the direction parallel to the thickness direction Z and away from the substrate 10, the dimension of the first isolation portion 42 in the first direction X gradually decreases. In other words, in the direction gradually away from the substrate 10, the cross-sectional size of the first isolation portion 42 gradually decreases. Thus, the third orthographic projection T3 is the orthographic projection on the substrate 10 of the surface of the first isolation portion 42 facing the substrate 10.

In some embodiments, referring to FIG. 6, the third orthographic projection T3 overlaps the second orthographic projection T2.

Considering that some film layer structures located on the side of the first electrode layer 20 away from the substrate 10, such as the first encapsulation layer, need to contact the sidewall of the first isolation portion 42 and extend on the sidewall of the first isolation portion 42, in order to improve the extension reliability of this film layer structure on the first isolation portion 42, the third orthographic projection T3 is set to overlap the second orthographic projection T2 in the embodiment of the present application, this allows the orthographic projection of the sidewall of the first isolation portion 42 on the substrate 10 to be located within the second orthographic projection T2, improving the flatness of the sidewall of the first isolation portion 42, thereby improving the manufacturing yield of the display panel 100.

In some embodiments, as shown in FIGS. 4 and 6, overlapping widths of a plurality of different regions of the second orthographic projection T2 of a same first electrode 21 with the third orthographic projection T3 are the same.

Considering that the third orthographic projection T3 will overlap the periphery of the second orthographic projection T2 at different positions, the directions of the overlapping widths at different regions of the second orthographic projection T2 are different. Specifically, referring to FIG. 6, the overlapping width of the overlapping region generated at the edge position of the second orthographic projection T2 in the first direction X with the third orthographic projection T3 refers to the dimension of the overlapping region in the first direction X. The overlapping width of the overlapping region generated at the edge position of the second orthographic projection T2 in the second direction Y with the third orthographic projection T3 refers to the dimension of the overlapping region in the second direction Y.

Further, in the embodiment of the present application, in addition to adjusting the morphology of the first electrode 21, the size of the first electrode 21 is also limited, so that the overlapping widths of the plurality of different regions of the second orthographic projection T2 of the same first electrode 21 with the third orthographic projection T3 are the same. This helps to further reduce the overlapping area between the second orthographic projection T2 and the third orthographic projection T3, reduce the parasitic capacitance between the first electrode 21 and the isolation structure 40, and improve the use reliability of the display panel.

In some embodiments, as shown in FIGS. 4 and 6, the light-emitting functional layer 30 includes a plurality of first light-emitting structures 31a for emitting light of a first color. The overlapping widths D1 of the second orthographic projections T2 of the first electrodes 21 corresponding to different first light-emitting structures 31a with the third orthographic projection T3 are the same.

The first light-emitting structure 31a is a light-emitting structure 31 among the plurality of light-emitting structures 31 for emitting light of a specific color. The corresponding light-emitting color of the first light-emitting structure 31a is not limited in the embodiment of the present application. For example, the first light-emitting structure 31a can be used to emit red light, blue light, or green light.

Based on the foregoing, at least a part of the graphic outer contour shape of the second orthographic projection T2 is the same as the outer contour shape of the first opening pattern K1, and the size of the second orthographic projection T2 is also positively correlated with the size of the first opening pattern K1. Further, the outer contour shape of the sixth orthographic projection of the light-emitting structure 31 is usually also the same as the outer contour shape of the first opening pattern K1, and the sizes of the sixth orthographic projection and the first opening pattern K1 are positively correlated.

On this basis, for a plurality of first light-emitting structures 31a of the same color, the outer contour shapes and sizes of the second orthographic projections T2 of the corresponding different first electrodes 21 can usually remain consistent, and the morphologies and sizes of the first isolation portions 42 surrounding the plurality of first light-emitting structures 31a are usually also the same or similar. In view of this, the overlapping widths of the second orthographic projections T2 of the first electrodes 21 corresponding to different first light-emitting structures 31a with the third orthographic projection T3 can remain the same. This design ensures that the overlapping areas between the plurality of first electrodes 21 corresponding to different first light-emitting structures 31a and the first isolation portion 42 are the same, so that the influences of the isolation structure 40 on different first light-emitting structures 31a are the same, resulting in consistent display effects for the first light-emitting structures 31a at different positions.

In some embodiments, referring to FIG. 4, the light-emitting functional layer 30 includes a first light-emitting structure 31a for emitting light of a first color and a second light-emitting structure 31b for emitting light of a second color. The overlapping width D1 of the second orthographic projection T2 corresponding to the first light-emitting structure 31a with the third orthographic projection T3 is different from the overlapping width D2 of the second orthographic projection T2 corresponding to the second light-emitting structure 31b with the third orthographic projection T3.

The first light-emitting structure 31a and the second light-emitting structure 31b are light-emitting structures 31 for emitting light of different colors. For example, the first light-emitting structure 31a and the second light-emitting structure 31b are used to emit different ones of red light, green light, and blue light, respectively. Since the first light-emitting structure 31a and the second light-emitting structure 31b emit light of different colors, they are prepared in different steps during the manufacturing process. For ease of understanding, the subsequent description in the embodiment of the present application will use the example where the second light-emitting structure 31b is formed before the first light-emitting structure 31a.

During the manufacturing process, firstly, light-emitting material, electrode material, and encapsulation material are formed in a stacked manner in all isolation openings 41. This light-emitting material is used to form the second light-emitting structure 31b, this electrode material is used to form the second electrode 51 corresponding to the second light-emitting structure 31b, and this encapsulation material is used to form the encapsulation portion corresponding to the second light-emitting structure 31b. Then, the light-emitting material, the electrode material, and the encapsulation material in a part of the isolation openings 41 are etched away, and the light-emitting material, the electrode material, and the encapsulation material in the remaining part of the isolation openings 41 are retained to form the second light-emitting structure 31b as well as the second electrode 51 and the encapsulation portion corresponding to the second light-emitting structure 31b. Then, the above steps are repeated to form the first light-emitting structure 31a as well as the second electrode 51 and the encapsulation portion 811 corresponding to the first light-emitting structure 31a.

In the etching process mentioned above, since a part of the isolation openings 41 are affected by etching while the other part of the isolation openings 41 are not, the etching medium will have an etching effect on the sidewall of the first isolation portion 42 around the part of the isolation openings 41, while the sidewall of the first isolation portion 42 around the other part of the isolation openings 41 will not be affected or will be less affected. In this case, the degree of etching on the sidewall of the first isolation portion 42 around the first light-emitting structure 31a and the degree of etching on the sidewall of the first isolation portion 42 around the second light-emitting structure 31b will be different, resulting in the overlapping width of the second orthographic projection T2 corresponding to the first light-emitting structure 31a with the third orthographic projection T3 being different from the overlapping width of the second orthographic projection T2 corresponding to the second light-emitting structure 31b with the third orthographic projection T3.

In some optional embodiments, as shown in FIG. 4, under a condition that the second light-emitting structure 31b is formed before the first light-emitting structure 31a, the overlapping width D1 of the second orthographic projection T2 corresponding to the first light-emitting structure 31a with the third orthographic projection T3 is smaller than the overlapping width D2 of the second orthographic projection T2 corresponding to the second light-emitting structure 31b with the third orthographic projection T3.

In some embodiments, the second isolation portion 43 has a fourth orthographic projection on the substrate 10. The fourth orthographic projection defines a plurality of third opening patterns. At least a part of the graphic outer contour shape of the second orthographic projection T2 is the same as the outer contour shape of the third opening pattern.

The fourth orthographic projection is an orthographic projection of the second isolation portion 43 on the substrate 10. Since the orthographic projection of the first isolation portion 42 on the substrate 10 is located within the orthographic projection of the second isolation portion 43 on the substrate 10, the first orthographic projection T1 of the isolation structure 40 can coincide with the fourth orthographic projection of the second isolation portion 43. On this basis, since the third opening pattern is an opening pattern defined by the fourth orthographic projection, the first opening pattern K1 can also coincide with the third opening pattern. In other words, the morphologies and sizes of the fourth orthographic projection and the third opening pattern are the same as the structure shown in FIG. 2.

Further, the morphology, size, and shape of the first electrode 21 are adjusted in the embodiment of the present application. By changing the morphology of the first electrode 21, at least a part of the graphic outer contour shape of the second orthographic projection T2 is set to be the same as the outer contour shape of the third opening pattern. This helps to reduce the overall size of the first electrode 21 and reduce the overlapping area between the fourth orthographic projection and the second orthographic projection T2. This design can reduce the parasitic capacitance between the isolation structure 40 and the first electrode 21, improve the reliability of signal transmission of the isolation structure 40 and the first electrode 21, and enhance the display reliability of the display panel 100.

In some embodiments, the fourth orthographic projection overlaps the second orthographic projection T2. This design allows the second orthographic projection T2 to have a certain area size, thereby improving the signal transmission capability of the first electrode 21 and the control reliability of the first electrode 21 over the light-emitting structure 31.

In some embodiments, the overlapping widths of a plurality of different regions of the second orthographic projection T2 of a same first electrode 21 with the fourth orthographic projection T4 are the same.

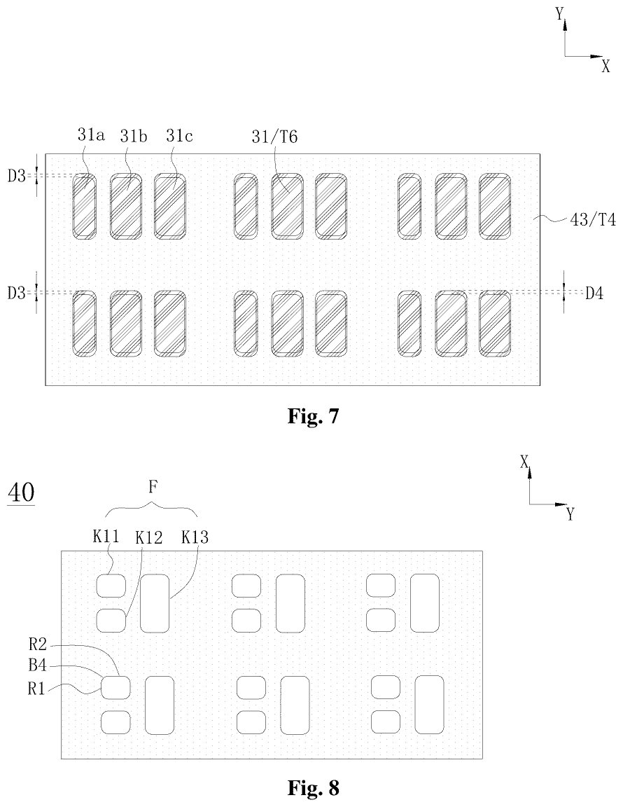

Considering that the fourth orthographic projection T4 will overlap the periphery of the second orthographic projection T2 at different positions, the directions of the overlapping widths at different regions of the second orthographic projection T2 are different. Specifically, referring to FIG. 7, the overlapping width of the overlapping region generated at the edge position of the second orthographic projection T2 in the first direction X with the fourth orthographic projection T4 refers to the dimension of the overlapping region in the first direction X. The overlapping width of the overlapping region generated at the edge position of the second orthographic projection T2 in the second direction Y with the fourth orthographic projection T4 refers to the dimension of the overlapping region in the second direction Y.

Further, in the embodiment of the present application, in addition to adjusting the morphology of the first electrode 21, the size of the first electrode 21 is also limited, so that the overlapping widths of the plurality of different regions of the second orthographic projection T2 of the same first electrode 21 with the fourth orthographic projection T4 are the same. This helps to further reduce the overlapping difference between the single second orthographic projection T2 and the fourth orthographic projection T4 at different edge regions, improving the use reliability of the display panel 100.

In some embodiments, as shown in FIG. 7, the light-emitting structure 31 has a sixth orthographic projection T6 on the substrate 10. The light-emitting functional layer 30 includes a plurality of first light-emitting structures 31a for emitting light of a first color. The overlapping widths D3 of the sixth orthographic projections T6 of different first light-emitting structures 31a with the fourth orthographic projection T4 are the same.

There are a plurality of first light-emitting structures 31a. For the plurality of first light-emitting structures 31a, the morphologies and sizes of different first light-emitting structures 31a are usually consistent, and the morphologies and sizes of the first isolation portions 42 surrounding the plurality of first light-emitting structures 31a are usually also the same or similar. On this basis, since the sixth orthographic projection T6 is the orthographic projection of the light-emitting structure 31 on the substrate 10, the overlapping widths of the sixth orthographic projections T6 of different first light-emitting structures 31a with the fourth orthographic projection T4 can remain the same, so that the second isolation portion 43 has the same shielding effect on different first light-emitting structures 31a, thereby reducing the display differences corresponding to different first light-emitting structures 31a and improving the display uniformity of the display panel 100.

In some embodiments, as shown in FIG. 1, the light-emitting functional layer 30 includes a plurality of first light-emitting structures 31a for emitting light of a first color. The overlapping widths D4 of the second orthographic projections T2 of the first electrodes 21 corresponding to different first light-emitting structures 31a with the fourth orthographic projection are the same.

It should be noted that since the first orthographic projection T1 of the isolation structure 40 and the fourth orthographic projection T4 of the second isolation portion 43 coincide with each other, D4 shown in FIG. 1 can represent the overlapping width D4 of the second orthographic projection T2 of the first electrode 21 corresponding to the first light-emitting structure 31a with the fourth orthographic projection.

Based on the foregoing, at least a part of the graphic outer contour shape of the second orthographic projection T2 is the same as the outer contour shape of the first opening pattern K1, and the size of the second orthographic projection T2 is also positively correlated with the size of the first opening pattern K1. Further, the outer contour shape of the sixth orthographic projection T6 of the light-emitting structure 31 is usually also the same as the outer contour shape of the first opening pattern K1, and the sizes of the sixth orthographic projection T6 and the first opening pattern K1are positively correlated.

On this basis, for a plurality of first light-emitting structures 31a of the same color, the outer contour shapes and sizes of the second orthographic projections T2 of the corresponding different first electrodes 21 can usually remain consistent, and the morphologies and sizes of the second isolation portions 43 surrounding the plurality of first light-emitting structures 31a are usually also the same or similar.

In view of this, the overlapping widths of the second orthographic projections T2 of the first electrodes 21 corresponding to different first light-emitting structures 31a with the fourth orthographic projection can remain the same. Further, since the first orthographic projection T1 of the isolation structure 40 can coincide with the fourth orthographic projection of the second isolation portion 43, the overlapping widths of the second orthographic projections T2 of the first electrodes 21 corresponding to different first light-emitting structures 31a with the first orthographic projection T1 can also remain the same, thereby improving the reliability of the relative position between the first electrode 21 and the isolation structure 40.

In some embodiments, as shown in FIG. 1, the light-emitting functional layer 30 includes a first light-emitting structure 31a for emitting light of a first color and a second light-emitting structure 31b for emitting light of a second color. The overlapping width D4 of the second orthographic projection T2 of the first electrode 21 corresponding to the first light-emitting structure 31a with the fourth orthographic projection is the same as the overlapping width D5 of the second orthographic projection T2 of the first electrode 21 corresponding to the second light-emitting structure 31b with the fourth orthographic projection.

Based on the foregoing, since the first light-emitting structure 31a and the second light-emitting structure 31b are prepared sequentially in different steps, during the preparation process, the degree of etching on the sidewall of the first isolation portion 42 around the first light-emitting structure 31a and the degree of etching on the sidewall of the first isolation portion 42 around the second light-emitting structure 31b will be different. This results in the overlapping width of the second orthographic projection T2 corresponding to the first light-emitting structure 31a with the third orthographic projection T3 being different from the overlapping width of the second orthographic projection T2 corresponding to the second light-emitting structure 31b with the third orthographic projection T3.

However, due to the different material composition of the second isolation portion 43 and the first isolation portion 42, the second isolation portion 43 is usually not affected by etching or is less affected. In view of this, the degree of etching on the second isolation portion 43 around the first light-emitting structure 31a and the degree of etching on the second isolation portion 43 around the second light-emitting structure 31b usually does not differ or differs little. On this basis, the overlapping width D4 of the second orthographic projection T2 of the first electrode 21 corresponding to the first light-emitting structure 31a with the fourth orthographic projection can be the same as the overlapping width D5 of the second orthographic projection T2 of the first electrode 21 corresponding to the second light-emitting structure 31b with the fourth orthographic projection.

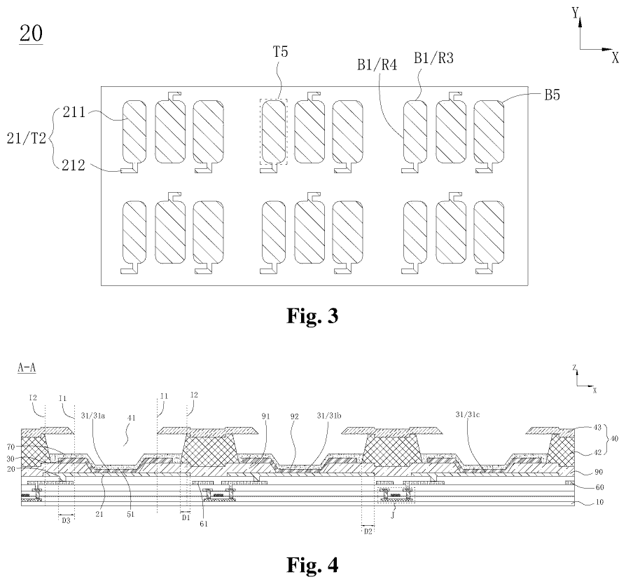

In some embodiments, as shown in FIGS. 3 and 4, the first electrode 21 includes a body portion 211 and a connection portion 212 connected to the body portion 211. The substrate 10 includes a pixel circuit. The body portion 211 is electrically connected to the pixel circuit through the connection portion 212.

The pixel circuit is a circuit structure used to control the signal voltage in the first electrode 21. The pixel circuit can have various forms, which is not limited in the embodiment of the present application. For example, the structure of the pixel circuit can be 7T1C, that is, a single pixel circuit includes seven thin film transistors and one storage capacitor, or the structure of the pixel circuit can be 8T2C, that is, a single pixel circuit includes eight thin film transistors and two storage capacitors.

The first electrode 21 includes the body portion 211 and the connection portion 212. The body portion 211 is the main component of the first electrode 21. The orthographic projection of the light-emitting structure 31 on the substrate 10 can overlap the orthographic projection of the body portion 211 on the substrate 10. The connection portion 212 is a part of the first electrode 21 used to connect the body portion 211 to the pixel electrode. Optionally, the connection portion 212 and the body portion 211 are an integral structure, that is, they include the same material and are formed in the same process.

In the embodiment of the present application, the first electrode 21 achieves positional correspondence with the light-emitting structure 31 through the body portion 211, and connects the body portion 211 to the pixel circuit through the connection portion 212. In this way, the connection position between the pixel circuit and the first electrode 21 is not limited to the region where the light-emitting structure 31 is located, thereby reducing the connection difficulty between the pixel circuit and the first electrode 21 and helping to reduce the layout difficulty of the relative position between the light-emitting structure 31 and the pixel circuit.

In some embodiments, the body portion 211 has a fifth orthographic projection T5 on the substrate 10. The outer contour shape of the fifth orthographic projection T5 is the same as the outer contour shape of the first opening pattern K1. In FIG. 3, the position of the fifth orthographic projection T5 is indicated by a dashed box.

In the embodiment of the present application, since the isolation structure 40 can shield the conductor structure or the semiconductor structure inside the substrate 10, the size of the first electrode 21 can be appropriately reduced. On this basis, the fifth orthographic projection T5 is the orthographic projection of the body portion 211 on the substrate 10. By setting the outer contour shape of the fifth orthographic projection T5 to be the same as the outer contour shape of the first opening pattern K1, the fifth orthographic projection T5 and the first opening pattern K1 can be conformal to each other, thus through this conformal design between them, the area of the fifth orthographic projection T5 can be reduced, and the overlapping area of the fifth orthographic projection T5 with the first orthographic projection T1 can be reduced, thereby reducing the parasitic capacitance between the isolation structure 40 and the body portion 211 and improving the reliability of signal transmission of the isolation structure 40 and the body portion 211.

It should be noted that the fifth orthographic projection T5 is a part of the second orthographic projection T2, and a part of the outer contour of the fifth orthographic projection T5 also belongs to the outer contour of the second orthographic projection T2, while the other part of the outer contour of the fifth orthographic projection T5 is connected to the orthographic projection of the connection portion 212 on the substrate 10. In addition, the specific positional relationship between the connection portion 212 and the isolation structure 40 is not limited in the embodiment of the present application. Optionally, the orthographic projection of the connection portion 212 on the substrate 10 overlaps the first orthographic projection T1.

In some embodiments, as shown in FIGS. 1 to 3, the overlapping width between the fifth orthographic projection T5 and the first orthographic projection T1 is L1, where 0.6 μm≤L1≤2.5 μm. Optionally, L1 is one of 0.6 μm, 1 μm, 1.5 μm, 2 μm, and 2.5 μm.

In the embodiment of the present application, by setting L1 to be no greater than 2.5 μm, the overlapping area between the isolation structure 40 and the first electrode 21 on the substrate 10 is reduced, the parasitic capacitance between the isolation structure 40 and the first electrode 21 is lowered, and the reliability of signal transmission of the isolation structure 40 and the first electrode 21 is improved. At the same time, L1 is set to be no less than 0.6 μm to meet the alignment accuracy between the isolation structure 40 and the first electrode 21, improve the positional reliability between the first electrode 21 and the corresponding light-emitting structure 31, and enhance the manufacturing yield of the display panel 100.

In some embodiments, as shown in FIGS. 4 and 6, the isolation structure 40 includes a first isolation portion 42 and a second isolation portion 43 located on a side of the first isolation portion 42 away from the substrate 10. The orthographic projection of the first isolation portion 42 on the substrate 10 is located within the orthographic projection of the second isolation portion 43 on the substrate 10. The overlapping width between the fifth orthographic projection T5 and the orthographic projection of the first isolation portion 42 on the substrate 10 is L2, where 0<L2≤1 μm. Optionally, L2 is one of 0.1 μm, 0.2 μm, 0.5 μm, 0.8 μm, and 1 μm. In FIG. 5, the overlapping width L2 is the distance D2 shown in the figure.

In the embodiment of the present application, considering that normally, the first isolation portion 42 is the main part of the isolation structure 40 that can generate parasitic capacitance with the first electrode 21, L2 is set to be no greater than 1 μm, thereby reducing the overlapping area between the first isolation portion 42 and the first electrode 21 on the substrate 10, lowering the parasitic capacitance between the first isolation portion 42 and the first electrode 21, and improving the reliability of signal transmission of the first isolation portion 42 and the first electrode 21. At the same time, L2 is set to be greater than 0, so that there can be an overlapping region between the first isolation portion 42 and the first electrode 21 on the substrate 10. This allows the first isolation portion 42 to be supported by the first electrode 21 at the sidewall position while meeting the alignment accuracy requirements, thereby improving the flatness of the sidewall of the first isolation portion 42, enhancing the preparation reliability of some film layer structures extending at the sidewall of the first isolation portion 42, and improving the manufacturing yield of the display panel 100.

In some embodiments, as shown in FIGS. 1 to 4, the fifth orthographic projection T5 includes a first straight edge B1. The first opening pattern K1 includes a second straight edge B2. The first straight edge B1 is parallel to the second straight edge B2. The “parallel” mentioned in the embodiment of the present application means that the overall extension directions of the two structures can be substantially parallel, and does not require them to be completely parallel. The “parallel” mentioned later in the present application is similar, and will not be repeated later in the present application.

In related technologies, the cathode in the cathode layer is usually only one and has a full-surface structure. However, in the embodiment of the present application, due to the presence of the isolation structure 40, the second electrode layer 50 can include a plurality of second electrodes 51 disposed corresponding to the plurality of isolation openings 41.

On this basis, the morphology of the isolation structure 40 is adaptively adjusted in the embodiment of the present application, so that the first opening pattern K1 includes a second straight edge B2. The design of the second straight edge B2 allows the second electrode 51 to contact the isolation structure 40 at the position corresponding to the second straight edge B2, thereby improving the connection effect between the second electrode 51 and the isolation structure 40, and enhancing the transmission reliability of the corresponding signal between the isolation structure 40 and the second electrode 51.

Further, the morphology of the first electrode 21 is also adjusted in the embodiment of the present application, so that the fifth orthographic projection T5 includes a first straight edge B1, and the first straight edge B1 is parallel to the second straight edge B2. This helps to improve the conformal effect between the first opening pattern K1 and the fifth orthographic projection T5, thereby helping to reduce the parasitic capacitance between the first electrode 21 and the isolation structure 40.

The specific extension direction of the first straight edge B1 and the second straight edge B2 is not limited in the embodiment of the present application. Optionally, the display panel 100 further includes a scan line. The first straight edge B1 is parallel or perpendicular to the scan line. The scan line is a wiring structure for transmitting scan signals. Depending on the needs of the actual display panel, the scan line can be parallel to the first straight edge B1, or perpendicular to the first straight edge B1.

In some embodiments, the light-emitting structure 31 has a sixth orthographic projection T6 on the substrate 10. The outer contour shape of the sixth orthographic projection T6 is the same as the outer contour shape of the corresponding first opening pattern K1.

In the embodiment of the present application, at least a part of the second orthographic projection T2 of the first electrode 21 and the sixth orthographic projection T6 of the light-emitting structure 31 can both be the same as the outer contour shape of the first opening pattern K1. In this way, the morphological designs of the light-emitting structure 31, the first electrode 21, and the isolation opening 41 can correspond to each other in pairs, which helps to improve the positional reliability among the light-emitting structure 31, the first electrode 21, and the isolation opening 41. At the same time, it also helps to reduce the size of the second orthographic projection T2 of the first electrode 21, thereby reducing the parasitic capacitance between the first electrode 21 and the isolation structure 40, and improving the reliability of signal transmission of the first electrode 21 and the isolation structure 40.

In some embodiments, as shown in FIGS. 1 to 7, the sixth orthographic projection T6 includes a third straight edge B3. The first opening pattern K1 includes a second straight edge B2. The third straight edge B3 is parallel to the second straight edge B2.

In the embodiment of the present application, the morphology of the isolation structure 40 is adaptively adjusted, so that the first opening pattern K1 includes a second straight edge B2. The design of the second straight edge B2 allows the second electrode 51 to contact the isolation structure 40 at the position corresponding to the second straight edge B2, thereby improving the connection effect between the second electrode 51 and the isolation structure 40, and enhancing the transmission reliability of the corresponding signal between the isolation structure 40 and the second electrode 51.

Further, the morphology of the light-emitting structure 31 is also adjusted in the embodiment of the present application, so that the sixth orthographic projection T6 includes a third straight edge B3, and the third straight edge B3 is parallel to the second straight edge B2. This helps to improve the conformal effect between the first opening pattern K1 and the sixth orthographic projection T6, reduce the impact of the isolation structure 40 on the light-emitting effect of the light-emitting structure 31, and improve the viewing experience of the display panel 100.

In some optional embodiments, the display panel 100 further includes a scan line. The third straight edge B3 is parallel or perpendicular to the scan line.

In some embodiments, as shown in FIG. 4, the display panel 100 further includes a second electrode layer 50 disposed on a side of the light-emitting functional layer 30 away from the substrate 10. The second electrode layer 50 includes a plurality of second electrodes 51 disposed in the plurality of isolation openings 41.

In the embodiment of the present application, similar to the light-emitting functional layer 30, the second electrode layer 50 also includes a plurality of second electrodes 51 corresponding to the plurality of isolation openings 41. The light-emitting structures 31 of the same color and the corresponding second electrodes 51 can be formed together in the same process. For the second electrodes 51 corresponding to the light-emitting structures 31 of different colors, they are independently formed in different processes. This also allows the preparation of the plurality of second electrodes 51 without the need for the fine metal mask, thereby reducing the manufacturing cost of the display panel 100.

In some embodiments, the second electrode 51 has a seventh orthographic projection on the substrate 10. The outer contour shape of the seventh orthographic projection is the same as the outer contour shape of the first opening pattern K1.

In the embodiment of the present application, the seventh orthographic projection is the orthographic projection of the second electrode 51 on the substrate 10. By setting the outer contour shape of the seventh orthographic projection to be the same as the outer contour shape of the first opening pattern K1, the shape matching degree between the second electrode 51 and the isolation structure 40 is improved, thereby improving the contact effect between the second electrode 51 and the isolation structure 40, further strengthening the electrical connection between the second electrode 51 and the isolation structure 40, and improving the signal transmission reliability among the plurality of second electrodes 51. Optionally, the isolation structure 40 includes a first isolation portion 42 and a second isolation portion 43 located on a side of the first isolation portion 42 away from the substrate 10. The second electrode 51 is in contact with the sidewall of the first isolation portion 42.

In some embodiments, the seventh orthographic projection includes a fourth straight edge. The first opening pattern K1 includes a second straight edge B2. The fourth straight edge is parallel to the second straight edge B2.

In the embodiment of the present application, the morphology of the isolation structure 40 is adaptively adjusted, so that the first opening pattern K1 includes a second straight edge B2. The design of the second straight edge B2 allows the second electrode 51 to contact the isolation structure 40 at the position corresponding to the second straight edge B2, thereby improving the connection effect between the second electrode 51 and the isolation structure 40, and enhancing the transmission reliability of the corresponding signal between the isolation structure 40 and the second electrode 51.

Further, the morphology of the second electrode 51 is also adjusted in the embodiment of the present application, so that the seventh orthographic projection includes a fourth straight edge, and the fourth straight edge is parallel to the second straight edge B2. In this way, the second electrode 51 can achieve connection with the isolation structure 40 at the position of the fourth straight edge, thereby improving the connection reliability between the second electrode 51 and the isolation structure 40, and enhancing the signal transmission reliability between the second electrode 51 and the isolation structure 40.

In some optional embodiments, the display panel 100 further includes a scan line. The fourth straight edge is parallel or perpendicular to the scan line.

In some embodiments, as shown in FIG. 4, the display panel 100 further includes a pixel definition layer 90 located on a side of the isolation structure 40 facing the substrate 10. The pixel definition layer 90 includes a pixel definition portion 91 and a pixel opening 92 enclosed and formed by the pixel definition portion. An outer contour shape of an orthographic projection of the pixel opening 92 on the substrate 10 is the same as the outer contour shape of the first opening pattern K1.

The pixel definition layer 90 is a film layer structure used to define the positions of different light-emitting structures 31. The pixel definition layer 90 includes the pixel definition portion 91 and the pixel opening 92 enclosed and formed by the pixel definition portion 91. The pixel definition portion 91 is the solid structure in the pixel definition layer 90. The pixel opening 92 is enclosed and formed by the pixel definition portion 91, and a plurality of pixel openings 92 are spaced apart from each other. Here, different pixel openings 92 are used to accommodate different light-emitting structures 31, and the shape of the orthographic projection of the light-emitting structure 31 on the substrate 10 is usually the same as the shape of the orthographic projection of the pixel opening 92 on the substrate 10, and the corresponding orthographic projection areas of the light-emitting structure 31 and the pixel opening 92 are often positively correlated. Optionally, the light-emitting structure 31 has a sixth orthographic projection T6 on the substrate 10. The outer contour shape of the sixth orthographic projection T6 is the same as the outer contour shape of the orthographic projection of the corresponding pixel opening 92 on the substrate 10.

On this basis, in the embodiment of the present application, by adjusting the structure of the pixel definition layer 90, the outer contour shape of the orthographic projection of the pixel opening 92 on the substrate 10 is set to be the same as the outer contour shape of the first opening pattern K1. This allows the outer contour shape of the sixth orthographic projection T6 to be the same as the outer contour shape of the first opening pattern K1, achieving the conformal design between the light-emitting structure 31 and the isolation opening 41, and helping to improve the light-emitting reliability of the light-emitting structure 31.

In some embodiments, as shown in FIG. 2, the first opening pattern K1 includes a plurality of straight edges and a first arc edge B4, adjacent two straight edges of the first opening pattern K1 are connected by the first arc edge B5.

In the embodiment of the present application, adjacent two straight edges of the first opening pattern K1 are connected by the first arc edge B4. Correspondingly, the isolation structure 40 has an arc structure corresponding to the first arc edge B4, which is beneficial for forming the desired shape when etching the isolation structure 40.

In some embodiments, the second orthographic projection T2 includes a plurality of straight edges and a second arc edge B5, adjacent two straight edges of the second orthographic projection T2 are connected by the second arc edge B5.

In the embodiment of the present application, the first opening pattern K1 corresponding to the isolation structure 40 has the first arc edge B4. In order to match the orthographic projection shapes of the isolation opening 41 and the first electrode 21, the second orthographic projection T2 of the first electrode 21 has a second arc edge B5 corresponding to the first arc edge B4, thereby improving the conformal effect between the isolation opening 41 and the first electrode 21.

In some embodiments, as shown in FIGS. 1 to 3, for a same light-emitting structure 31, a radius of curvature of the second arc edge B5 corresponding to the light-emitting structure 31 is greater than a radius of curvature of the first arc edge B4 corresponding to the light-emitting structure 31.

In some embodiments, the light-emitting functional layer 30 includes a first light-emitting structure 31a and a second light-emitting structure 31b with different light-emitting colors. A radius of curvature of the first arc edge B4 of the first opening pattern K1 corresponding to the first light-emitting structure 31a is different from a radius of curvature of the first arc edge B4 of the first opening pattern K1 corresponding to the second light-emitting structure 31b.

In the embodiment of the present application, the radii of curvature of the rounded corner structures of the sixth orthographic projections of light-emitting structures 31 of different colors are usually different. Therefore, the radius of curvature of the first arc edge B4 of the first opening pattern K1 corresponding to the first light-emitting structure 31a is set to be different from the radius of curvature of the first arc edge B4 of the first opening pattern K1 corresponding to the second light-emitting structure 31b. This allows the first opening pattern K1 corresponding to the first light-emitting structure 31a to match the shape of the sixth orthographic projection of the first light-emitting structure 31a, and the first opening pattern K1 corresponding to the second light-emitting structure 31b to match the shape of the sixth orthographic projection of the second light-emitting structure 31b, thereby improving the display performance.

Similarly, in some embodiments, the radius of curvature of the second arc edge B5 of the second orthographic projection T2 corresponding to the first light-emitting structure 31a is different from the radius of curvature of the second arc edge B2 of the second orthographic projection T2 corresponding to the second light-emitting structure 31b.

In some embodiments, as shown in FIGS. 1 to 3, the plurality of first opening patterns K1 include at least one first sub-opening K11, at least one second sub-opening K12, and at least one third sub-opening K13. The first sub-opening K11, the second sub-opening K12, and the third sub-opening K13 respectively correspond to light-emitting structures 31 of different colors. The plurality of first opening patterns K1 constitute a repeating unit F. A plurality of repeating units F are repeatedly arranged. The repeating unit F includes a first sub-opening K11, a second sub-opening K12, and a third sub-opening K13, and the first sub-opening K11 and the second sub-opening K12 are arranged side by side in a first direction X.

The first sub-opening K11, the second sub-opening K12, and the third sub-opening K13 respectively correspond to light-emitting structures 31 of different colors. For example, the plurality of light-emitting structures 31 include a first light-emitting structure 31a, a second light-emitting structure 31b, and a third light-emitting structure 31c that are different in color. The orthographic projection of the first light-emitting structure 31a on the substrate 10 can overlap the first sub-opening K11, the orthographic projection of the second light-emitting structure 31b on the substrate 10 can overlap the second sub-opening K12, and the orthographic projection of the third light-emitting structure 31c on the substrate 10 can overlap the third sub-opening K13.

The arrangement of the plurality of different first opening patterns K1 usually corresponds to the arrangement of the corresponding plurality of light-emitting structures 31. Moreover, a plurality of adjacent light-emitting structures 31 can together form a pixel unit. The pixel unit is the smallest repeating unit composed of a plurality of light-emitting structures 31, and a plurality of pixel units can be repeatedly arranged along a specific direction. In view of this, the plurality of first opening patterns K1 can constitute a repeating unit F corresponding to the pixel unit, and a plurality of repeating units F are repeatedly arranged.

Further, the number and types as well as the arrangement of the plurality of light-emitting structures 31 in a single pixel unit can be consistent with the number and types as well as the arrangement of the plurality of first opening patterns K1 in a single repeating unit F. On this basis, the repeating unit F includes a first sub-opening K11, a second sub-opening K12, and a third sub-opening K13, and the first sub-opening K11 and the second sub-opening K12 are arranged side by side in the first direction X. This indicates that the pixel unit includes a first light-emitting structure 31a, a second light-emitting structure 31b, and a third light-emitting structure 31c, and the first light-emitting structure 31a and the second light-emitting structure 31b are arranged side by side in the first direction X.

In addition, the positional relationship between the second sub-opening K12 and the third sub-opening K13 in a single repeating unit F is not limited in the embodiment of the present application. Optionally, as shown in FIG. 2, in the repeating unit F, the third sub-opening K13 is located on a side of the second sub-opening K12 away from the first sub-opening K11 along the first direction X. This indicates that in the pixel unit, the third light-emitting structure 31c can be located on a side of the second light-emitting structure 31b away from the first sub-opening K11 along the first direction X. Or, as shown in FIG. 8, the third sub-opening K13 is located on the same side of the first sub-opening K11 and the second sub-opening K12 along a second direction Y. The first direction X and the second direction Y intersect. This indicates that in the pixel unit, the third light-emitting structure 31c can be located on the same side of the first light-emitting structure 31a and the second light-emitting structure 31b along the second direction Y. Optionally, the first direction X, the second direction Y, and the thickness direction Z are perpendicular to each other.

In the embodiment of the present application, depending on actual needs, the conformal design of the second orthographic projection T2 and the first opening pattern K1 can be applied to the arrangement structures shown in FIG. 2 or FIG. 8. In other words, the conformal design of the second orthographic projection T2 and the first opening pattern K1 can be applied to various types of pixel arrangement structures to meet the needs of different display panels 100 for reducing parasitic capacitance, and has strong flexibility and applicability.

In some embodiments, as shown in FIGS. 2, 3, and 8, the first opening pattern K1 includes a first edge R1 parallel to the first direction X and a second edge R2 parallel to the second direction Y. The second orthographic projection T2 includes a third edge R3 parallel to the first direction X and a fourth edge R4 parallel to the second direction Y. The first direction X and the second direction Y intersect.

For the above two types of pixel arrangements, the first opening pattern K1 can include a first edge R1 and a second edge R2. Both the first edge R1 and the second edge R2 are straight edges of the first opening pattern K1, but their corresponding extension directions are different. The first edge R1 extends along the first direction X, and the second edge R2 extends along the second direction Y.

The third edge R3 is a straight structure in the second orthographic projection T2 corresponding to the first edge R1. The fourth edge R4 is a straight structure in the second orthographic projection T2 corresponding to the second edge R2. The provision of the third edge R3 and the fourth edge R4 allows at least a part of the structure of the second orthographic projection T2 to be conformal with the first opening pattern K1, which helps to reduce the area size of the second orthographic projection T2 and reduce the parasitic capacitance between the first electrode 21 and the isolation structure 40.

Based on the foregoing, due to the presence of the isolation structure 40, the second electrode layer 50 can include a plurality of second electrodes 51 disposed corresponding to the plurality of isolation openings 41. On this basis, to meet display needs, the plurality of second electrodes 51 need to be scanned and transmitted sequentially in a specific straight-line direction to meet the transmission needs of the corresponding power signals.

On this basis, depending on actual needs, the first direction X can be the scanning direction of the plurality of second electrodes 51. Thus, the first edge R1 is a straight structure parallel to the scanning direction of the plurality of second electrodes 51. In this design, the first edge R1 can improve the signal transmission efficiency and accuracy of the plurality of second electrodes 51, thereby improving the display reliability of the display panel 100. Similarly, in other cases, the second direction Y can be the scanning direction of the plurality of second electrodes 51. Thus, the second edge R2 is a straight structure parallel to the scanning direction of the plurality of second electrodes 51. In this design, the second edge R2 can improve the signal transmission efficiency and accuracy of the plurality of second electrodes 51, thereby improving the display reliability of the display panel 100.

It should be noted that the first edge R1 and the second edge R2 are usually arranged alternately around the center of the first opening pattern K1. For the first edge R1 and the second edge R2 which are the closest to each other, they can be directly connected, or other straight or curved structures can be provided between them, which is not limited in the embodiment of the present application.

In some embodiments, the first opening pattern K1 further includes a first arc edge B4 connecting the first edge R1 and the second edge R2. The second orthographic projection T2 further includes a second arc edge B5 connecting the third edge R3 and the fourth edge R4.

In the embodiment of the present application, considering that the sixth orthographic projection of the light-emitting structure 31 can include rounded corner structures, the morphologies of the isolation structure 40 and the first electrode 21 are adjusted, so that the first opening pattern K1 includes the first arc edge B4 corresponding to the rounded corner structure and connecting the first edge R1 and the second edge R2, and the second orthographic projection T2 includes the second arc edge B5 corresponding to the rounded corner structure and connecting the third edge R3 and the fourth edge R4. This allows the shapes of the isolation opening 41 and the first electrode 21 to better match the shape of the light-emitting structure 31, thereby improving the light-emitting effect of the light-emitting structure 31 and helping to reduce the parasitic capacitance between the first electrode 21 and the isolation structure 40.

In some embodiments, referring to FIG. 9, the plurality of first opening patterns K1 include a first sub-opening K11, a second sub-opening K12, and a third sub-opening K13. The first sub-opening K11, the second sub-opening K12, and the third sub-opening K13 respectively correspond to light-emitting structures 31 of different colors. The centers of at least two first sub-openings K11 and the centers of at least two second sub-openings K12 form a first virtual polygon N1. The centers of the first sub-openings K11 are located at first vertexes of the first virtual polygon N1. The centers of the second sub-openings K12 are located at second vertexes of the first virtual polygon N1. The first vertices and the second vertices are alternately arranged in the first virtual polygon N1. The third sub-opening K13 is located inside the first virtual polygon N1.

The centers of at least four third sub-openings K13 form a second virtual polygon N2. The centers of a third sub-openings K13 are located at vertexes of the second virtual polygon N2. The first sub-opening K11 or the second sub-opening K12 is located inside the second virtual polygon N2.

The plurality of first opening patterns K1 can be arranged not only in the manner shown in FIGS. 2 and 8 but also in the manner shown in FIG. 9. In the arrangement of FIG. 9, the centers of at least two first sub-openings K11 and the centers of at least two second sub-openings K12 form the first virtual polygon N1. The “center” mentioned here refers to the geometric center of the corresponding structural pattern. The “first virtual polygon N1” is a virtual polygon formed by sequentially connecting the centers of at least two first sub-openings K11 and two second sub-openings K12. Here, the first virtual polygon N1 can be a quadrilateral, a hexagon, an octagon, etc. Further, under a condition that the first virtual polygon N1 is a quadrilateral, the quadrilateral can be a rectangular structure such as a rectangle or a square, or other parallelograms besides the rectangle, or a trapezoidal structure, which is not limited in the embodiment of the present application.

The third sub-opening K13 is located inside the first virtual polygon N1. The center of the third sub-opening K13 can coincide with the center of the first virtual polygon N1, or they can be offset from each other, which is not limited in the embodiment of the present application. Moreover, for adjacent two first virtual polygons N1, they can share the center of one first sub-opening K11 and the center of one second sub-opening K12.

In addition to the first virtual polygon N1, the centers of at least four third sub-opening K13 patterns can also form a second virtual polygon N2. The “second virtual polygon N2” mentioned here is a virtual quadrilateral formed by sequentially connecting the centers of four third sub-openings K13. Here, the second virtual polygon N2 can be a quadrilateral, a hexagon, an octagon, etc. Further, under a condition that the second virtual polygon N2 is a quadrilateral, the quadrilateral is a rectangular structure such as a rectangle or a square, or other parallelograms besides the rectangle, or a trapezoidal structure, which is not limited in the embodiment of the present application.

The first sub-opening K11 or the second sub-opening K12 is located inside the second virtual polygon N2. For adjacent two second virtual polygons N2, one second virtual polygon N2 contains the first sub-opening K11, and the other second virtual polygon N2 contains the second sub-opening K12. Here, in a single second virtual polygon N2 containing the first sub-opening K11, the center of the first sub-opening K11 can coincide with the center of the second virtual polygon N2, or they can be offset from each other. Similarly, in a single second virtual polygon N2 containing the second sub-opening K12, the center of the second sub-opening K12 can coincide with the center of the second virtual polygon N2, or they can be offset from each other, which is not limited in the embodiment of the present application.

Considering that the arrangement of the plurality of different first opening patterns K1 usually corresponds to the arrangement of the corresponding plurality of light-emitting structures 31, optionally, the plurality of light-emitting structures 31 include a first light-emitting structure 31a, a second light-emitting structure 31b, and a third light-emitting structure 31c. The first light-emitting structure 31a, the second light-emitting structure 31b, and the third light-emitting structure 31c correspond to the first sub-opening K11, the second sub-opening K12, and the third sub-opening K13, respectively. The centers of at least two first light-emitting structures 31a and the centers of at least two second light-emitting structures 31b form a third virtual polygon. The centers of the first light-emitting structures 31a are located at third vertexes of the third virtual polygon. The centers of the second light-emitting structures 31b are located at fourth vertexes of the third virtual polygon. The third vertices and the fourth vertices are alternately arranged in the third virtual polygon. The third light-emitting structure 31c is located inside the third virtual polygon.

The centers of at least four third light-emitting structures 31c form a fourth virtual polygon. The centers of the third light-emitting structures 31c are located at vertexes of the fourth virtual polygon. The first light-emitting structure 31a or the second light-emitting structure 31b is located inside the fourth virtual polygon.

In the embodiment of the present application, depending on actual needs, the conformal design of the second orthographic projection T2 and the first opening pattern K1 can also be applied to the arrangement structure shown in FIG. 8. In other words, the conformal design of the second orthographic projection T2 and the first opening pattern K1 can be applied to various types of pixel arrangement structures to meet the needs of different display panels 100 for reducing parasitic capacitance, and has strong flexibility and applicability.

In some embodiments, the center of the third sub-opening K13 coincides with the center of the first virtual polygon N1; or, in the first virtual polygon N1, the center of the third sub-opening K13 is at the same distance from the centers of at least two second sub-openings K12, and the center of the third sub-opening K13 is at the same distance from the centers of at least two first sub-openings K11.

Considering that the relative positional relationship of the plurality of light-emitting structures 31 usually corresponds to the positional relationship of the plurality of first opening patterns K1, in the embodiment of the present application, the center of the third light-emitting structure 31c can coincide with the center of the third virtual polygon; or, in the third virtual polygon, the center of the third light-emitting structure 31c is at the same distance from the centers of at least two second light-emitting structures 31b, and the center of the third light-emitting structure 31c is at the same distance from the centers of at least two first light-emitting structures 31a.

This design can reduce the risk of the distance between a single third light-emitting structure 31c and an adjacent first light-emitting structure 31a being too small or too large, and can also reduce the risk of the distance between a single third light-emitting structure 31c and an adjacent second light-emitting structure 31b being too small or too large, thereby helping to improve the display performance of the display panel 100.

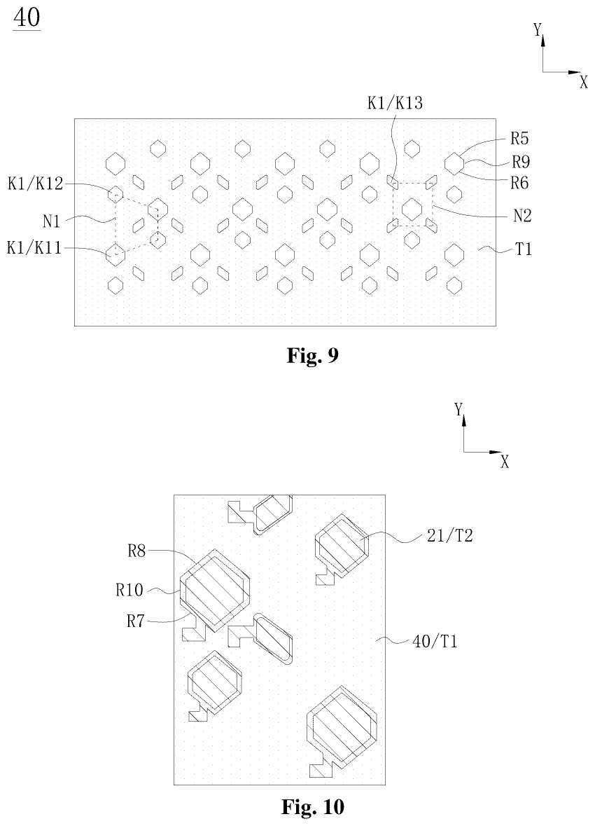

In some embodiments, as shown in FIGS. 9 and 10, the first opening pattern K1 includes a fifth edge R5 extending along a third direction and a sixth edge R6 extending along a fourth direction. The fifth edge R5 and the sixth edge R6 are alternately arranged. The second orthographic projection T2 includes a seventh edge R7 extending along the third direction and an eighth edge R8 extending along the fourth direction. The seventh edge R7 and the eighth edge R8 are alternately arranged. The plurality of third sub-openings K13 are arranged in an array along the first direction X and the second direction Y. The first direction X, the second direction Y, the third direction, and the fourth direction intersect each other.

Referring to the figure, in this arrangement, the first direction X and the second direction Y correspond to the two arrangement directions of the plurality of third sub-openings K13. For example, for a rectangular display panel 100, the first direction X and the second direction Y can be the length and width directions of the display panel 100, respectively. Further optionally, the display panel 100 further includes a scan line. One of the first direction X and the second direction Y is parallel to the scan line, and the other is perpendicular to the scan line.

For the third direction and the fourth direction, both directions intersect the first direction X and the second direction Y, and they intersect each other. Optionally, the angle between the third direction and the first direction X can be one of 30°, 45°, or 60°. The angle between the fourth direction and the first direction X can also be one of 30°, 45°, or 60°.

Considering that in this arrangement, the sixth orthographic projection of the light-emitting structure 31 usually includes a straight structure extending along the third direction and a straight structure extending along the fourth direction, thus, the morphologies of the isolation structure 40 and the second electrode 51 are adjusted in the embodiment of the present application, so that the first opening pattern K1 includes a fifth edge R5 extending along the third direction and a sixth edge R6 extending along the fourth direction. The fifth edge R5 and the sixth edge R6 are alternately arranged. The second orthographic projection T2 includes a seventh edge R7 extending along the third direction and an eighth edge R8 extending along the fourth direction. The seventh edge R7 and the eighth edge R8 are alternately arranged.

In this design, the second orthographic projection T2 can achieve a conformal setting with the first opening pattern K1 through the seventh edge R7 and the eighth edge R8, thereby reducing the overlapping area between the isolation structure 40 and the first electrode 21 and reducing parasitic capacitance. At the same time, the morphologies of the second orthographic projection T2 and the first opening pattern K1 can better match the sixth orthographic projection, thereby improving the control accuracy of the first electrode 21 over the light-emitting structure 31 and the positional reliability of the light-emitting structure 31 relative to the isolation opening 41, and improving the light-emitting effect of the display panel 100.

In some embodiments, as shown in FIGS. 9 and 10, the first opening pattern K1 further includes a first connecting edge R9 extending along the first direction X. Two fifth edges R5, two first connecting edges R9, and two sixth edges R6 are connected end to end in sequence. The second orthographic projection T2 further includes a second connecting edge R10 extending along the first direction X. Two seventh edges R7, two second connecting edges R10, and two eighth edges R8 are connected end to end in sequence.

In the embodiment of the present application, the morphology of the isolation structure 40 is adaptively adjusted, so that the first opening pattern K1 includes the first connecting edge R9. The design of the first connecting edge R9 allows the second electrode 51 to contact the isolation structure 40 at the position corresponding to the first connecting edge R9, thereby improving the connection effect between the second electrode 51 and the isolation structure 40, and enhancing the transmission reliability of the corresponding signal between the isolation structure 40 and the second electrode 51.

Further, the morphology of the first electrode 21 is also adjusted in the embodiment of the present application, so that the fifth orthographic projection T5 includes the second connecting edge R10, and the first connecting edge R9 is parallel to the second connecting edge R10. This helps to improve the conformal effect between the first opening pattern K1 and the fifth orthographic projection T5, thereby helping to reduce the parasitic capacitance between the first electrode 21 and the isolation structure 40.

In some embodiments, as shown in FIG. 4, the display panel 100 includes a first conductor layer 60 disposed on a side of the first electrode layer 20 facing the substrate 10. The first conductor layer 60 includes a first signal line 61.

The display panel 100 can have a plurality of conductor layers disposed on the side of the first electrode layer 20 facing the substrate 10, and the first conductor layer 60 can be the conductor layer closest to the first electrode layer 20 among these conductor layers. Optionally, the display panel 100 further includes a second conductor layer disposed on a side of the first conductor layer 60 facing the substrate 10.

The first signal line 61 is a wiring structure located in the first conductor layer 60 and used to transmit a specific voltage signal. The specific type of the first signal line 61 is not limited in the embodiment of the present application. Optionally, the first signal is used to transmit one of a data signal (data) and a power signal (vdd).

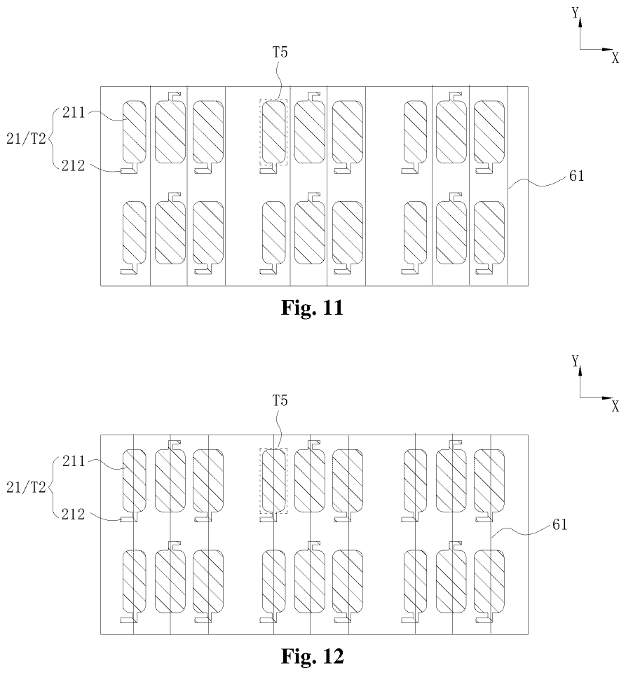

In addition, the first electrode layer 20 and the first signal line 61 can also have various positional relationships. In some optional embodiments, as shown in FIGS. 1, 4, and 11, the orthographic projection of the first signal line 61 on the substrate 10 is located between adjacent second orthographic projections T2. In this design, the presence of the first signal line 61 will not cause local elevation of the first electrode 21, thereby helping to improve the overall flatness of the first electrode 21.

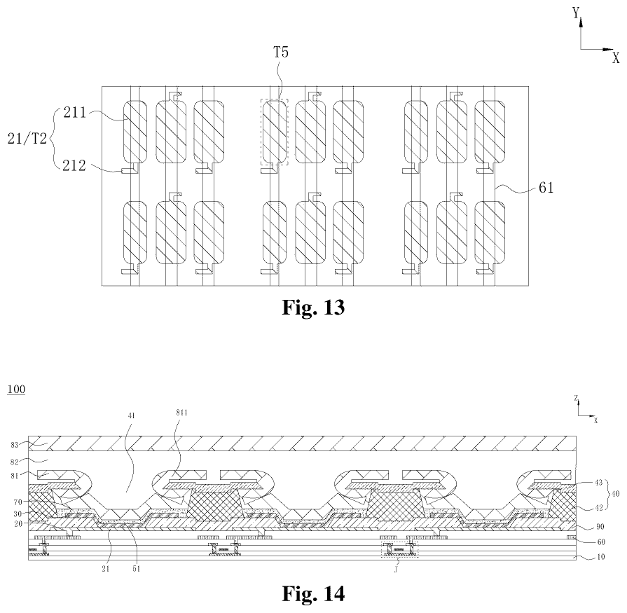

Or, considering that in some cases, referring to FIGS. 12 and 13, the internal structure layout of the first conductor layer 60 is relatively compact, and relying solely on the region between adjacent second orthographic projections T2 cannot meet the layout needs of the first signal line 61. Therefore, in other optional embodiments, the first electrode 21 includes a body portion 211. The body portion 211 has a fifth orthographic projection T5 on the substrate 10. The orthographic projection of the first signal line 61 on the substrate 10 overlaps the fifth orthographic projection T5.

Further, the fifth orthographic projection T5 may only overlap the orthographic projection of a single first signal line 61 on the substrate 10, or the fifth orthographic projection T5 may simultaneously overlap the orthographic projections of a plurality of first signal lines 61 on the substrate 10, which is not limited in the embodiment of the present application.

In some embodiments, as shown in FIG. 12, the fifth orthographic projection T5 overlaps the orthographic projection of a single first signal line 61 on the substrate 10, and the fifth orthographic projection T5 is symmetric with respect to the orthographic projection of the single first signal line 61 on the substrate 10.

It should be noted that the first signal line 61 can be a straight linear structure, or the first signal line 61 can have bends at local positions but overall be approximately linear. The phrase “the fifth orthographic projection T5 is symmetric with respect to the orthographic projection of the single first signal line 61 on the substrate 10” means that the fifth orthographic projection T5 has a central axis, and the orthographic projection of the part of the first signal line 61 corresponding to the fifth orthographic projection T5 on the substrate 10 can coincide with the central axis or be spaced apart with the central axis within a small distance range. Here, the central axis is a virtual straight line passing through the center of the fifth orthographic projection T5 and parallel to the first signal line 61.

In the embodiment of the present application, by setting the fifth orthographic projection T5 to be symmetric with respect to the orthographic projection of the single first signal line 61 on the substrate 10, the layout needs of the first signal line 61 are met while allowing the surface of the first electrode 21 away from the substrate 10 to be in a symmetric state. This enables the first electrode 21 to have the same supporting effect on the different structures on both sides of the isolation opening 41 in the isolation structure 40, thereby improving the extension reliability of some film layers at the sidewall of the isolation structure 40, and improving the manufacturing yield of the display panel 100.

In other embodiments, as shown in FIG. 13, the fifth orthographic projection T5 overlaps orthographic projections of a plurality of first signal lines 61 on the substrate 10. The orthographic projections of the plurality of first signal lines 61 overlapping the fifth orthographic projection T5 on the substrate 10 are symmetric with respect to a central axis of the fifth orthographic projection T5.

In the embodiment of the present application, by setting the fifth orthographic projection T5 to overlap the orthographic projections of the plurality of first signal lines 61 on the substrate 10, the layout difficulty of the plurality of first signal lines 61 is further reduced. At the same time, the orthographic projections of the plurality of first signal lines 61 overlapping the fifth orthographic projection T5 on the substrate 10 are set to be symmetric with respect to the central axis of the fifth orthographic projection T5, so that the surface of the first electrode 21 away from the substrate 10 is in a symmetric state. This enables the first electrode 21 to have the same supporting effect on the different structures on both sides of the isolation opening 41 in the isolation structure 40, thereby improving the extension reliability of some film layers at the sidewall of the isolation structure 40, and improving the manufacturing yield of the display panel 100.

In some embodiments, referring to FIG. 14, the display panel 100 further includes a first encapsulation layer 81 disposed on a side of the light-emitting functional layer 30 away from the substrate 10. The first encapsulation layer 81 includes an encapsulation portion 811 disposed corresponding to the isolation opening 41.

The first encapsulation layer 81 is a film layer structure used to encapsulate and protect the light-emitting functional layer 30. The first encapsulation layer 81 includes encapsulation portions 811 respectively provided in the plurality of isolation openings 41. Here, the encapsulation portions 811 can be formed simultaneously with the light-emitting structures 31 and the first electrodes 21, and the plurality of encapsulation portions 811 can correspond to the plurality of light-emitting structures 31, so as to achieve independent encapsulation of the plurality of light-emitting structures 31 and improve encapsulation reliability.

In addition, the encapsulation portion 811 is also a structure in the display panel 100 that contacts the isolation structure 40 and extends along the sidewall of the isolation structure 40, thereby improving the structural reliability of the encapsulation portion 811. In some embodiments, under a condition that the display panel 100 includes the first signal line 61, the orthographic projection of the first signal line 61 on the substrate 10 can be set to be located between adjacent second orthographic projections T2. Alternatively, the fifth orthographic projection T5 can overlap the orthographic projection of a single first signal line 61 on the substrate 10, and the fifth orthographic projection T5 is symmetric with respect to the orthographic projection of the single first signal line 61 on the substrate 10. Alternatively, the fifth orthographic projection T5 can overlap the orthographic projections of the plurality of first signal lines 61 on the substrate 10, and the orthographic projections of the plurality of first signal lines 61 overlapping the fifth orthographic projection T5 on the substrate 10 are symmetric with respect to the central axis of the fifth orthographic projection T5.

In some embodiments, the outer contour shape of the orthographic projection of the encapsulation portion 811 on the substrate 10 is the same as the outer contour shape of the first opening pattern K1.

In the embodiment of the present application, considering that the sixth orthographic projection of the light-emitting structure 31 is usually the same as the outer contour shape of the first opening pattern K1, in the embodiment of the present application, the outer contour shape of the orthographic projection of the encapsulation portion 811 on the substrate 10 is also set to be the same as the outer contour shape of the first opening pattern K1. This allows the orthographic projection of the encapsulation portion 811 on the substrate 10 to match the sixth orthographic projection, thereby improving the relative positional reliability between the encapsulation portion 811 and the light-emitting structure 31 and the encapsulation reliability of the encapsulation portion 811 for the light-emitting structure 31.

In addition to the first encapsulation layer 81, in some optional embodiments, the display panel 100 further includes a second encapsulation layer 82 disposed on a side of the first encapsulation layer 81 away from the substrate 10, and a third encapsulation layer 83 located on a side of the second encapsulation layer 82 away from the substrate 10.

Unlike the first encapsulation layer 81, the second encapsulation layer 82 and the third encapsulation layer 83 can be planar structures, that is, the orthographic projections of the second encapsulation layer 82 and the third encapsulation layer 83 on the substrate 10 can cover the orthographic projections of the plurality of encapsulation portions 811 on the substrate 10. Further, through the cooperation of the first encapsulation layer 81, the second encapsulation layer 82, and the third encapsulation layer 83, the encapsulation protection effect on the light-emitting functional layer 30 is further enhanced, thereby improving the use reliability of the display panel 100.

The material composition of the first encapsulation layer 81, the second encapsulation layer 82, and the third encapsulation layer 83 is not limited in the embodiment of the present application. Optionally, the first encapsulation layer 81 and the third encapsulation layer 83 include inorganic materials, and the second encapsulation layer 82 includes organic materials.

In a second aspect, an embodiment of the present application provides a display panel 100. The display panel 100 includes a substrate 10, a first electrode layer 20, an isolation structure 40, and a light-emitting functional layer 30. The first electrode layer 20 is disposed on a side of the substrate 10 and includes a plurality of first electrodes 21 spaced apart. The isolation structure 40 is disposed on a side of the substrate 10 and is provided with a plurality of isolation openings 41. An orthographic projection of a first electrode 21 on the substrate 10 overlaps an orthographic projection of an isolation opening 41 on the substrate 10. The light-emitting functional layer 30 is disposed on a side of the first electrode layer 20 away from the substrate 10 and includes a light-emitting structure 31 disposed corresponding to the first electrode 21.

The isolation structure 40 has a first orthographic projection T1 on the substrate 10. The first orthographic projection T1 defines a plurality of first opening patterns K1. The first electrode 21 has a second orthographic projection T2 on the substrate 10. The first opening pattern K1 overlaps the second orthographic projection T2, and at least a part of the graphic outer contour shape of the second orthographic projection T2 is the same as the outer contour shape of the first opening pattern K1.

The substrate 10 is a structure in the display panel 100 for carrying other film layers. The substrate 10 includes a plurality of film layer structures. The specific composition of the film layer structures inside the substrate 10 is not limited in the embodiments of the present application. The plurality of film layer structures inside the substrate 10 and the plurality of film layer structures outside the substrate 10 are all stacked along the thickness direction Z of the substrate 10. The thickness direction Z of different film layer structures, the thickness direction Z of the display panel 100, and the thickness direction Z of the substrate 10 are usually parallel. Therefore, for ease of understanding, the thickness direction Z of different film layer structures, the thickness direction Z of the display panel 100, and the thickness direction Z of the substrate 10 are all indicated by the same direction in the drawings.

The first electrode layer 20 and the light-emitting functional layer 30 are disposed on the same side of the substrate 10 along the thickness direction Z, and the light-emitting functional layer 30 is located on the side of the first electrode layer 20 away from the substrate 10 along the thickness direction Z. The light-emitting functional layer 30 is a functional film layer in the display panel 100 for achieving the display effect, and the first electrode layer 20 is an electrode film layer for controlling whether the light-emitting functional layer 30 emits light. Optionally, the display panel 100 further includes a second electrode layer 50 located on the side of the light-emitting functional layer 30 away from the substrate 10. The first electrode layer 20 and the second electrode layer 50 cooperate with each other to control whether the light-emitting functional layer 30 emits light. Exemplarily, the first electrode layer 20 is an anode layer, and the second electrode layer 50 is a cathode layer.

The first electrode layer 20 includes a plurality of first electrodes 21 spaced apart. The light-emitting functional layer 30 includes a light-emitting structure 31 disposed corresponding to the first electrode 21. The phrase “a light-emitting structure 31 disposed corresponding to the first electrode 21” mentioned here means that the orthographic projection of each light-emitting structure 31 on the substrate 10 can overlap the orthographic projection of one first electrode 21 on the substrate 10. Depending on actual needs, a single first electrode 21 may correspond to only a single light-emitting structure 31, that is, a single first electrode 21 is only used to control a single light-emitting structure 31; or a single first electrode 21 may correspond to the plurality of light-emitting structures 31, that is, a single first electrode 21 can also be used to control the plurality of light-emitting structures 31. For ease of understanding, the subsequent description in the embodiments of the present application will use the example where a single first electrode 21 corresponds to only a single light-emitting structure 31.

The light-emitting structure 31 include, but is not limited to, a red light-emitting structure 31 for emitting red light, a green light-emitting structure 31 for emitting green light, and a blue light-emitting structure 31 for emitting blue light. Each light-emitting structure 31 may include stacked film layers such as a Hole Inject Layer (HIL), a Hole Transport Layer (HTL), a light-emitting layer, an Electron Inject Layer (EIL), and an Electron Transport Layer (ETL). In some other embodiments, the light-emitting structure 31 may include a plurality of light-emitting layers stacked, and a charge generation layer is provided between adjacent light-emitting layers.

The isolation structure 40 is a structure in the display panel 100 for separating different light-emitting structures 31. The isolation structure 40 encloses and forms a plurality of isolation openings 41. The plurality of isolation openings 41 respectively correspond to the plurality of light-emitting structures 31 and the plurality of first electrodes 21. That is, the orthographic projection of a single isolation opening 41 on the substrate 10 can overlap the orthographic projection of a single light-emitting structure 31 on the substrate 10, and at the same time, can also overlap the orthographic projection of a single first electrode 21 on the substrate 10.

The provision of the isolation structure 40 allows the light-emitting functional layer 30 to form a plurality of light-emitting structures 31 spaced apart without the need for a fine metal mask, thereby reducing the manufacturing cost of the display panel 100. Specifically, taking the red light-emitting structure 31 being prepared before the green light-emitting structure 31 as an example, since the fine metal mask is eliminated, the red light-emitting material corresponding to the red light-emitting structure 31 first falls into each isolation opening 41. Then, the red light-emitting material in a part of the isolation openings 41 is selectively etched away, and the red light-emitting material in the remaining part of the isolation openings 41 is retained to form the red light-emitting structure 31. After that, the green light-emitting material corresponding to the green light-emitting structure 31 falls into each isolation opening 41. Then, the green light-emitting material in a part of the isolation openings 41 is selectively etched away, and the green light-emitting material in the remaining part of the isolation openings 41 is retained to form the green light-emitting structure 31.

The first orthographic projection T1 is the orthographic projection of the isolation structure 40 on the substrate 10. Due to the presence of the isolation openings 41, the first orthographic projection T1 can define a plurality of first opening patterns K1. Considering that the cross-sectional area of the isolation structure 40 at different positions in the thickness direction Z may not be completely consistent, the first orthographic projection T1 is the orthographic projection corresponding to the position where the isolation structure 40 has the maximum cross-sectional area, and the first opening pattern K1 is the opening pattern defined and surrounded by the first orthographic projection T1.

Similarly, similar as the isolation structure 40, the radial dimension of the isolation opening 41 at different positions in the thickness direction Z is not completely consistent. Therefore, the orthographic projection of the isolation opening 41 on the substrate 10 is the orthographic projection corresponding to the position where the isolation opening 41 has the maximum radial dimension. The position where the isolation opening 41 has the maximum radial dimension is usually aligned with the position where the isolation structure 40 has the minimum cross-sectional area. Thus, it can be seen that the first opening pattern K1 is not the orthographic projection of the isolation opening 41 on the substrate 10. Referring to FIG. 4, the orthographic projection of the virtual line I1 on the substrate can coincide with the outer contour of the first opening pattern K1, and the orthographic projection of the virtual line I2 on the substrate can coincide with the outer contour of the orthographic projection of the isolation opening 41 on the substrate 10. Further optionally, the graphic outer contour shape of the orthographic projection of the isolation opening 41 on the substrate 10 may be the same as the outer contour shape of the first opening pattern K1.

It should be noted that the “radial dimension” mentioned here refers to a dimension in a direction parallel to the plane of the substrate 10 at a specific position of the isolation opening 41. It does not limit the shape of the isolation opening 41. The orthographic projection of the isolation opening 41 on the substrate 10 and the first opening pattern K1 may be a circular shape, a polygonal shape, or other regular or irregular shapes, which is not limited in the embodiments of the present application.

The second orthographic projection T2 is the orthographic projection of the first electrode 21 on the substrate 10. The second orthographic projection T2 overlaps the first opening pattern K1. The orthographic projection of the light-emitting structure 31 on the substrate 10 also overlaps the first opening pattern K1. However, the specific positional relationship between the first orthographic projection T1 and the second orthographic projection T2 is not limited in the embodiments of the present application. For example, the first orthographic projection T1 and the second orthographic projection T2 may overlap, the end of the first electrode 21 is located below the isolation structure 40 and is insulated from the isolation structure 40. Alternatively, the second orthographic projection T2 may be located outside the first orthographic projection T1.

In related technologies, the display panel 100 often does not include an isolation structure 40, and a relatively large-sized anode structure needs to be provided to cover and shield a part of the conductor structure or the semiconductor structure inside the substrate 10, thereby reducing adverse effects caused by light shining on the conductor structure or the semiconductor structure.

However, in the embodiment of the present application, considering the presence of the isolation structure 40, if the size and morphology of the first electrode 21 are still set similar to those in the related art, the display performance of the display panel will be affected. For example, it may cause the first orthographic projection T1 and the second orthographic projection T2 to overlap and produce a large overlapping area. Further, since at least a part of the structure in the isolation structure 40 can be set to include conductive material, that is, at least a part of the structure in the isolation structure 40 can be a conductor structure or a semiconductor structure. Therefore, this design is likely to cause a large parasitic capacitance between the isolation structure 40 and the first electrode 21, and create a risk of signal crosstalk, affecting the reliability of signal transmission of the isolation structure 40 and the first electrode 21, and thus easily adversely affecting the display image.

In view of this, the embodiment of the present application adjusts the morphology, size, and shape of the first electrode 21. By changing the morphology of the first electrode 21, the second orthographic projection T2 is set to include a first straight edge B1 parallel to the second straight edge B2 in the first opening pattern K1, so that at least a part of the outer contour shape of the second orthographic projection T2 can match the outer contour shape of the first opening pattern K1, this helps to reduce the overall size of the first electrode 21 and reduce the overlapping area between the first orthographic projection T1 and the second orthographic projection T2, and this design can reduce the parasitic capacitance between them, improve the reliability of signal transmission of the isolation structure 40 and the first electrode 21, and enhance the display reliability of the display panel 100.

Moreover, since the isolation structure 40 can also cover and shield a part of the conductor structure or the semiconductor structure inside the substrate 10, the adverse effects of factors such as light exposure on the conductor structure or the semiconductor structure can be reduced. Therefore, even if the size of the first electrode 21 is reduced in the embodiment of the present application, it will not affect the performance reliability of the conductor structure or the semiconductor structure inside the substrate 10, thereby helping to further improve the use reliability of the display panel 100.

In addition, in related technologies, the cathode in the cathode layer is usually only one and has a full-surface structure. However, in the embodiment of the present application, due to the presence of the isolation structure 40, the second electrode layer 50 can include a plurality of second electrodes 51 corresponding to the plurality of isolation openings 41.

On this basis, the morphology of the isolation structure 40 is adaptively adjusted in the embodiment of the present application, so that the first opening pattern K1 includes a second straight edge B2. The design of the second straight edge B2 allows the second electrode 51 to contact the isolation structure 40 at the position corresponding to the second straight edge B2, thereby improving the connection effect between the second electrode 51 and the isolation structure 40, and enhancing the transmission reliability of the corresponding signal between the isolation structure 40 and the second electrode 51.

In some embodiments, at least a part of the graphic outer contour shape of the second orthographic projection T2 is the same as the outer contour shape of the first opening pattern K1. In addition to the first straight edge B1 and the second straight edge B2, the outer contours of the second orthographic projection T2 and the first opening pattern K1 may also include other corresponding and similarly shaped structures, such as other corresponding parallel straight edges or corresponding curved edges.

In the embodiment of the present application, by further matching the outer contour shape of the second orthographic projection T2 with the outer contour shape of the first opening pattern K1, the overall size of the first electrode 21 is reduced, and the overlapping area between the first orthographic projection T1 and the second orthographic projection T2 is reduced, this design can reduce the parasitic capacitance between them, improve the reliability of signal transmission of the isolation structure 40 and the first electrode 21, and enhance the display reliability of the display panel 100.

It should be noted that the “same” mentioned here means that the outer contour shapes are substantially the same, and does not require complete consistency. The “same” mentioned later in the present application is similar, and will not be repeated later in the present application. Moreover, for the second orthographic projection T2, the graphic outer contour shape corresponding to the second orthographic projection T2 may be the same as the outer contour shape of the first opening pattern K1, or according to actual needs, a part of the graphic outer contour shape of the second orthographic projection T2 may also be different from the outer contour shape of the first opening pattern K1, which is not limited in the embodiments of the present application, as long as at least a part of the graphic outer contour shape of the second orthographic projection T2 is the same as the outer contour shape of the first opening pattern K1.

In some embodiments, as shown in FIG. 4, the isolation structure 40 includes a first isolation portion 42 and a second isolation portion 43 located on a side of the first isolation portion 42 away from the substrate 10. The orthographic projection of the first isolation portion 42 on the substrate 10 is located within the orthographic projection of the second isolation portion 43 on the substrate 10.

The specific size and shape of the first isolation portion 42 and the second isolation portion 43 are not limited in the embodiment of the present application. For example, the longitudinal section of the isolation structure 40 may be T-shaped, or the longitudinal section of the isolation structure 40 may be an inverted trapezoid. This design helps to prevent the light-emitting material from easily extending along the sidewall of the first isolation portion 42 to the sidewall of the second isolation portion 43 during the preparation of the light-emitting functional layer 30, thereby achieving the preparation and separation of the light-emitting structures 31 corresponding to different isolation openings 41 without the need for the fine metal mask.

The material composition of the first isolation portion 42 and the second isolation portion 43 is not limited in the embodiment of the present application. The first isolation portion 42 and the second isolation portion 43 may both include conductive material, or the first isolation portion 42 includes conductive material and the second isolation portion 43 includes insulating material, or the first isolation portion 42 and the second isolation portion 43 may both include insulating material.

In some embodiments, referring to FIGS. 1 to 5, the first isolation portion 42 has a third orthographic projection T3 on the substrate 10. The third orthographic projection T3 defines a plurality of second opening patterns K2. At least a part of the graphic outer contour shape of the second orthographic projection T2 is the same as the outer contour shape of the second opening pattern K2.

The third orthographic projection T3 is the orthographic projection of the first isolation portion 42 on the substrate 10. The third orthographic projection T3 can define a plurality of second opening patterns K2. Considering that the cross-sectional area of the first isolation portion 42 at different positions in the thickness direction Z may not be completely consistent, the third orthographic projection T3 is the orthographic projection corresponding to the position where the first isolation portion 42 has the maximum cross-sectional area, and the second opening pattern K2 is the opening pattern defined and surrounded by the third orthographic projection T3.

The second orthographic projection T2 is the orthographic projection of the first electrode 21 on the substrate 10. The second orthographic projection T2 overlaps the second opening pattern K2. Similarly, the orthographic projection of the light-emitting structure 31 on the substrate 10 also overlaps the second opening pattern K2. The specific positional relationship between the second orthographic projection T2 and the third orthographic projection T3 is not limited in the embodiment of the present application. For example, the second orthographic projection T2 and the third orthographic projection T3 may overlap, or the second orthographic projection T2 may be located outside the third orthographic projection T3.

For the first opening pattern K1 and the second opening pattern K2, since the orthographic projection of the first isolation portion 42 on the substrate 10 is located within the orthographic projection of the second isolation portion 43 on the substrate 10, the orthographic projection of the first isolation portion 42 on the substrate 10 will not coincide with the orthographic projection of the isolation structure 40 on the substrate 10, that is, the first orthographic projection T1 will not coincide with the third orthographic projection T3. Thus, the first opening pattern K1 and the second opening pattern K2 will not completely coincide. Optionally, the first opening pattern K1 is located within the second opening pattern K2, and the edge of the first opening pattern K1 is spaced apart from the edge of the second opening pattern K2. In FIG. 5, the outer contour of the first opening pattern K1 is indicated by a dashed line.

Further, in the embodiment of the present application, similar to the first opening pattern K1, at least a part of the graphic outer contour shape of the second orthographic projection T2 is also the same as the outer contour shape of the second opening pattern K2, thus through this conformal design between them, the shape matching degree between the first electrode 21 and the light-emitting structure 31 can be further improved, the driving performance of the first electrode 21 on the light-emitting structure 31 can be enhanced, and the display reliability of the display panel 100 can be improved.

In some optional embodiments, as shown in FIG. 4, the display panel 100 further includes a second electrode layer 50 disposed on a side of the light-emitting functional layer 30 away from the substrate 10. The second electrode layer 50 includes a second electrode 51 disposed corresponding to the isolation opening 41. The first isolation portion 42 includes conductive material. The second electrode 51 is in contact with and electrically connected to the sidewall of the first isolation portion 42.

The phrase “a second electrode 51 disposed corresponding to the isolation opening 41” mentioned here means that the orthographic projection of the second electrode 51 on the substrate 10 overlaps the orthographic projection of the isolation opening 41 on the substrate 10. Further, the orthographic projection of the second electrode 51 on the substrate 10 overlaps the first opening pattern K1.

The first isolation portion 42 includes conductive material and is used to transmit a corresponding power signal to the second electrode 51. On this basis, in order to reduce the parasitic capacitance between the first isolation portion 42 and the first electrode 21, at least a part of the graphic outer contour shape of the second orthographic projection T2 is set to be the same as the outer contour shape of the second opening pattern K2 in the embodiment of the present application, thus through this conformal design between them, the overlapping area between the second orthographic projection T2 and the third orthographic projection T3 can be reduced, thereby reducing the parasitic capacitance between them and improving the reliability of signal transmission of the first isolation portion 42 and the first electrode 21.

In some embodiments, as shown in FIG. 4, in a direction perpendicular to the display panel and away from the substrate 10, the dimension of the first isolation portion 42 in a first direction X gradually decreases. The first direction X is parallel to the plane of the substrate 10.

The direction perpendicular to the display panel is the thickness direction Z. The first direction X is a direction intersecting the thickness direction Z. Optionally, the first direction X is perpendicular to the thickness direction Z. In the direction parallel to the thickness direction Z and away from the substrate 10, the dimension of the first isolation portion 42 in the first direction X gradually decreases. In other words, in the direction gradually away from the substrate 10, the cross-sectional size of the first isolation portion 42 gradually decreases. Thus, the third orthographic projection T3 is the orthographic projection on the substrate 10 of the surface of the first isolation portion 42 facing the substrate 10.

In some embodiments, referring to FIG. 6, the third orthographic projection T3 overlaps the second orthographic projection T2.

Considering that some film layer structures located on the side of the first electrode layer 20 away from the substrate 10, such as the first encapsulation layer, need to contact the sidewall of the first isolation portion 42 and extend on the sidewall of the first isolation portion 42, in order to improve the extension reliability of this film layer structure on the first isolation portion 42, the third orthographic projection T3 is set to overlap the second orthographic projection T2 in the embodiment of the present application, this allows the orthographic projection of the sidewall of the first isolation portion 42 on the substrate 10 to be located within the second orthographic projection T2, thereby utilizing the first electrode 21 to support the first isolation portion 42 at the sidewall position, improving the flatness of the sidewall of the first isolation portion 42, reducing the risk of the first encapsulation layer breaking at the sidewall position of the first isolation portion 42, and thus improving the manufacturing yield of the display panel 100.

In some embodiments, as shown in FIGS. 4 and 6, overlapping widths of a plurality of different regions of the second orthographic projection T2 of a same first electrode 21 with the third orthographic projection T3 are the same.

Considering that the third orthographic projection T3 will overlap the periphery of the second orthographic projection T2 at different positions, the directions of the overlapping widths at different regions of the second orthographic projection T2 are different. Specifically, referring to FIG. 6, the overlapping width of the overlapping region generated at the edge position of the second orthographic projection T2 in the first direction X with the third orthographic projection T3 refers to the dimension of the overlapping region in the first direction X. The overlapping width of the overlapping region generated at the edge position of the second orthographic projection T2 in the second direction Y with the third orthographic projection T3 refers to the dimension of the overlapping region in the second direction Y.

Further, in the embodiment of the present application, in addition to adjusting the morphology of the first electrode 21, the size of the first electrode 21 is also limited, so that the overlapping widths of the plurality of different regions of the second orthographic projection T2 of the same first electrode 21 with the third orthographic projection T3 are the same. This helps to further reduce the overlapping area between the second orthographic projection T2 and the third orthographic projection T3, reduce the parasitic capacitance between the first electrode 21 and the isolation structure 40, and improve the use reliability of the display panel.

In some embodiments, as shown in FIGS. 4 and 6, the light-emitting functional layer 30 includes a plurality of first light-emitting structures 31a for emitting light of a first color. The overlapping widths D1 of the second orthographic projections T2 of the first electrodes 21 corresponding to different first light-emitting structures 31a with the third orthographic projection T3 are the same.

The first light-emitting structure 31a is a light-emitting structure 31 among the plurality of light-emitting structures 31 for emitting light of a specific color. The corresponding light-emitting color of the first light-emitting structure 31a is not limited in the embodiment of the present application. For example, the first light-emitting structure 31a can be used to emit red light, blue light, or green light.

Based on the foregoing, at least a part of the graphic outer contour shape of the second orthographic projection T2 is the same as the outer contour shape of the first opening pattern K1, and the size of the second orthographic projection T2 is also positively correlated with the size of the first opening pattern K1. Further, the outer contour shape of the sixth orthographic projection of the light-emitting structure 31 is usually also the same as the outer contour shape of the first opening pattern K1, and the sizes of the sixth orthographic projection and the first opening pattern K1 are positively correlated.

On this basis, for a plurality of first light-emitting structures 31a of the same color, the outer contour shapes and sizes of the second orthographic projections T2 of the corresponding different first electrodes 21 can usually remain consistent, and the morphologies and sizes of the first isolation portions 42 surrounding the plurality of first light-emitting structures 31a are usually also the same or similar. In view of this, the overlapping widths of the second orthographic projections T2 of the first electrodes 21 corresponding to different first light-emitting structures 31a with the third orthographic projection T3 can remain the same. This design ensures that the overlapping areas between the plurality of first electrodes 21 corresponding to different first light-emitting structures 31a and the first isolation portion 42 are the same, so that the influences of the isolation structure 40 on different first light-emitting structures 31a are the same, resulting in consistent display effects for the first light-emitting structures 31a at different positions.

In some embodiments, referring to FIG. 4, the light-emitting functional layer 30 includes a first light-emitting structure 31a for emitting light of a first color and a second light-emitting structure 31b for emitting light of a second color. The overlapping width D1 of the second orthographic projection T2 corresponding to the first light-emitting structure 31a with the third orthographic projection T3 is different from the overlapping width D2 of the second orthographic projection T2 corresponding to the second light-emitting structure 31b with the third orthographic projection T3.

The first light-emitting structure 31a and the second light-emitting structure 31b are light-emitting structures 31 for emitting light of different colors. For example, the first light-emitting structure 31a and the second light-emitting structure 31b are used to emit different ones of red light, green light, and blue light, respectively. Since the first light-emitting structure 31a and the second light-emitting structure 31b emit light of different colors, they are prepared in different steps during the manufacturing process. For ease of understanding, the subsequent description in the embodiment of the present application will use the example where the second light-emitting structure 31b is formed before the first light-emitting structure 31a.

During the manufacturing process, firstly, light-emitting material, electrode material, and encapsulation material are formed in a stacked manner in all isolation openings 41. This light-emitting material is used to form the second light-emitting structure 31b, this electrode material is used to form the second electrode 51 corresponding to the second light-emitting structure 31b, and this encapsulation material is used to form the encapsulation portion corresponding to the second light-emitting structure 31b. Then, the light-emitting material, the electrode material, and the encapsulation material in a part of the isolation openings 41 are etched away, and the light-emitting material, the electrode material, and the encapsulation material in the remaining part of the isolation openings 41 are retained to form the second light-emitting structure 31b as well as the second electrode 51 and the encapsulation portion corresponding to the second light-emitting structure 31b. Then, the above steps are repeated to form the first light-emitting structure 31a as well as the second electrode 51 and the encapsulation portion 811 corresponding to the first light-emitting structure 31a.

In the etching process mentioned above, since a part of the isolation openings 41 are affected by etching while the other part of the isolation openings 41 are not, the etching medium will have an etching effect on the sidewall of the first isolation portion 42 around the part of the isolation openings 41, while the sidewall of the first isolation portion 42 around the other part of the isolation openings 41 will not be affected or will be less affected. In this case, the degree of etching on the sidewall of the first isolation portion 42 around the first light-emitting structure 31a and the degree of etching on the sidewall of the first isolation portion 42 around the second light-emitting structure 31b will be different, resulting in the overlapping width of the second orthographic projection T2 corresponding to the first light-emitting structure 31a with the third orthographic projection T3 being different from the overlapping width of the second orthographic projection T2 corresponding to the second light-emitting structure 31b with the third orthographic projection T3.

In some optional embodiments, as shown in FIG. 4, under a condition that the second light-emitting structure 31b is formed before the first light-emitting structure 31a, the overlapping width D1 of the second orthographic projection T2 corresponding to the first light-emitting structure 31a with the third orthographic projection T3 is smaller than the overlapping width D2 of the second orthographic projection T2 corresponding to the second light-emitting structure 31b with the third orthographic projection T3.

In some embodiments, as shown in FIGS. 3 and 4, the first electrode 21 includes a body portion 211 and a connection portion 212 connected to the body portion 211. The substrate 10 includes a pixel circuit. The body portion 211 is electrically connected to the pixel circuit through the connection portion 212.

The pixel circuit is a circuit structure used to control the signal voltage in the first electrode 21. The pixel circuit can have various forms, which is not limited in the embodiment of the present application. For example, the structure of the pixel circuit can be 7T1C, that is, a single pixel circuit includes seven thin film transistors and one storage capacitor, or the structure of the pixel circuit can be 8T2C, that is, a single pixel circuit includes eight thin film transistors and two storage capacitors.

The first electrode 21 includes the body portion 211 and the connection portion 212. The body portion 211 is the main component of the first electrode 21. The orthographic projection of the light-emitting structure 31 on the substrate 10 can overlap the orthographic projection of the body portion 211 on the substrate 10. The connection portion 212 is a part of the first electrode 21 used to connect the body portion 211 to the pixel electrode. Optionally, the connection portion 212 and the body portion 211 are an integral structure, that is, they include the same material and are formed in the same process.

In the embodiment of the present application, the first electrode 21 achieves positional correspondence with the light-emitting structure 31 through the body portion 211, and connects the body portion 211 to the pixel circuit through the connection portion 212. In this way, the connection position between the pixel circuit and the first electrode 21 is not limited to the region where the light-emitting structure 31 is located, thereby reducing the connection difficulty between the pixel circuit and the first electrode 21 and helping to reduce the layout difficulty of the relative position between the light-emitting structure 31 and the pixel circuit.

In some embodiments, the body portion 211 has a fifth orthographic projection T5 on the substrate 10. The outer contour shape of the fifth orthographic projection T5 is the same as the outer contour shape of the first opening pattern K1. In FIG. 3, the position of the fifth orthographic projection T5 is indicated by a dashed box.

In the embodiment of the present application, since the isolation structure 40 can shield the conductor structure or the semiconductor structure inside the substrate 10, the size of the first electrode 21 can be appropriately reduced. On this basis, the fifth orthographic projection T5 is the orthographic projection of the body portion 211 on the substrate 10. By setting the outer contour shape of the fifth orthographic projection T5 to be the same as the outer contour shape of the first opening pattern K1, the fifth orthographic projection T5 and the first opening pattern K1 can be conformal to each other, thus through this conformal design between them, the area of the fifth orthographic projection T5 can be reduced, and the overlapping area of the fifth orthographic projection T5 with the first orthographic projection T1 can be reduced, thereby reducing the parasitic capacitance between the isolation structure 40 and the body portion 211 and improving the reliability of signal transmission of the isolation structure 40 and the body portion 211.

It should be noted that the fifth orthographic projection T5 is a part of the second orthographic projection T2, and a part of the outer contour of the fifth orthographic projection T5 also belongs to the outer contour of the second orthographic projection T2, while the other part of the outer contour of the fifth orthographic projection T5 is connected to the orthographic projection of the connection portion 212 on the substrate 10. In addition, the specific positional relationship between the connection portion 212 and the isolation structure 40 is not limited in the embodiment of the present application. Optionally, the orthographic projection of the connection portion 212 on the substrate 10 overlaps the first orthographic projection T1.

In some embodiments, as shown in FIGS. 1 to 3, the overlapping width between the fifth orthographic projection T5 and the first orthographic projection T1 is L1, where 0.6 μm≤L1≤2.5 μm. Optionally, L1 is one of 0.6 μm, 1 μm, 1.5 μm, 2 μm, and 2.5 μm.

In the embodiment of the present application, by setting L1 to be no greater than 2.5 μm, the overlapping area between the isolation structure 40 and the first electrode 21 on the substrate 10 is reduced, the parasitic capacitance between the isolation structure 40 and the first electrode 21 is lowered, and the reliability of signal transmission of the isolation structure 40 and the first electrode 21 is improved. At the same time, L1 is set to be no less than 0.6 μm to meet the alignment accuracy between the isolation structure 40 and the first electrode 21, improve the positional reliability between the first electrode 21 and the corresponding light-emitting structure 31, and enhance the manufacturing yield of the display panel 100.

In some embodiments, as shown in FIGS. 4 and 6, the isolation structure 40 includes a first isolation portion 42 and a second isolation portion 43 located on a side of the first isolation portion 42 away from the substrate 10. The orthographic projection of the first isolation portion 42 on the substrate 10 is located within the orthographic projection of the second isolation portion 43 on the substrate 10. The overlapping width between the fifth orthographic projection T5 and the orthographic projection of the first isolation portion 42 on the substrate 10 is L2, where 0<L2≤1 μm. Optionally, L2 is one of 0.1 μm, 0.2 μm, 0.5 μm, 0.8 μm, and 1 μm. In FIG. 5, the overlapping width L2 is the distance D2 shown in the figure.

In the embodiment of the present application, considering that normally, the first isolation portion 42 is the main part of the isolation structure 40 that can generate parasitic capacitance with the first electrode 21, L2 is set to be no greater than 1 μm, thereby reducing the overlapping area between the first isolation portion 42 and the first electrode 21 on the substrate 10, lowering the parasitic capacitance between the first isolation portion 42 and the first electrode 21, and improving the reliability of signal transmission of the first isolation portion 42 and the first electrode 21. At the same time, L2 is set to be greater than 0, so that there can be an overlapping region between the first isolation portion 42 and the first electrode 21 on the substrate 10. This allows the first isolation portion 42 to be supported by the first electrode 21 at the sidewall position while meeting the alignment accuracy requirements, thereby improving the flatness of the sidewall of the first isolation portion 42, enhancing the preparation reliability of some film layer structures extending at the sidewall of the first isolation portion 42, and improving the manufacturing yield of the display panel 100.

In some embodiments, as shown in FIGS. 1 to 4, the fifth orthographic projection T5 includes a first straight edge B1. The first opening pattern K1 includes a second straight edge B2. The first straight edge B1 is parallel to the second straight edge B2. The “parallel” mentioned in the embodiment of the present application means that the overall extension directions of the two structures can be substantially parallel. The “parallel” mentioned later in the present application is similar, and will not be repeated later in the present application.

In related technologies, the cathode in the cathode layer is usually only one and has a full-surface structure. However, in the embodiment of the present application, due to the presence of the isolation structure 40, the second electrode layer 50 can include a plurality of second electrodes 51 disposed corresponding to the plurality of isolation openings 41.

On this basis, the morphology of the isolation structure 40 is adaptively adjusted in the embodiment of the present application, so that the first opening pattern K1 includes a second straight edge B2. The design of the second straight edge B2 allows the second electrode 51 to contact the isolation structure 40 at the position corresponding to the second straight edge B2, thereby improving the connection effect between the second electrode 51 and the isolation structure 40, and enhancing the transmission reliability of the corresponding signal between the isolation structure 40 and the second electrode 51.

Further, the morphology of the first electrode 21 is also adjusted in the embodiment of the present application, so that the fifth orthographic projection T5 includes a first straight edge B1, and the first straight edge B1 is parallel to the second straight edge B2. This helps to improve the conformal effect between the first opening pattern K1 and the fifth orthographic projection T5, thereby helping to reduce the parasitic capacitance between the first electrode 21 and the isolation structure 40.

The specific extension direction of the first straight edge B1 and the second straight edge B2 is not limited in the embodiment of the present application. Optionally, the display panel 100 further includes a scan line. The first straight edge B1 is parallel or perpendicular to the scan line. The scan line is a wiring structure for transmitting scan signals. Depending on the needs of the actual display panel, the scan line can be parallel to the first straight edge B1, or perpendicular to the first straight edge B1.

In some embodiments, as shown in FIGS. 1 to 3, the plurality of first opening patterns K1 include at least one first sub-opening K11, at least one second sub-opening K12, and at least one third sub-opening K13. The first sub-opening K11, the second sub-opening K12, and the third sub-opening K13 respectively correspond to light-emitting structures 31 of different colors. The plurality of first opening patterns K1 constitute a repeating unit F. A plurality of repeating units F are repeatedly arranged. The repeating unit F includes a first sub-opening K11, a second sub-opening K12, and a third sub-opening K13, and the first sub-opening K11 and the second sub-opening K12 are arranged side by side in a first direction X.

The first sub-opening K11, the second sub-opening K12, and the third sub-opening K13 respectively correspond to light-emitting structures 31 of different colors. For example, the plurality of light-emitting structures 31 include a first light-emitting structure 31a, a second light-emitting structure 31b, and a third light-emitting structure 31c that are different in color. The orthographic projection of the first light-emitting structure 31a on the substrate 10 can overlap the first sub-opening K11, the orthographic projection of the second light-emitting structure 31b on the substrate 10 can overlap the second sub-opening K12, and the orthographic projection of the third light-emitting structure 31c on the substrate 10 can overlap the third sub-opening K13.

The arrangement of the plurality of different first opening patterns K1 usually corresponds to the arrangement of the corresponding plurality of light-emitting structures 31. Moreover, a plurality of adjacent light-emitting structures 31 can together form a pixel unit. The pixel unit is the smallest repeating unit composed of a plurality of light-emitting structures 31, and a plurality of pixel units can be repeatedly arranged along a specific direction. In view of this, the plurality of first opening patterns K1 can constitute a repeating unit F corresponding to the pixel unit, and a plurality of repeating units F are repeatedly arranged.

Further, the number and types as well as the arrangement of the plurality of light-emitting structures 31 in a single pixel unit can be consistent with the number and types as well as the arrangement of the plurality of first opening patterns K1 in a single repeating unit F. On this basis, the repeating unit F includes a first sub-opening K11, a second sub-opening K12, and a third sub-opening K13, and the first sub-opening K11 and the second sub-opening K12 are arranged side by side in the first direction X. This indicates that the pixel unit includes a first light-emitting structure 31a, a second light-emitting structure 31b, and a third light-emitting structure 31c, and the first light-emitting structure 31a and the second light-emitting structure 31b are arranged side by side in the first direction X.

In addition, the positional relationship between the second sub-opening K12 and the third sub-opening K13 in a single repeating unit F is not limited in the embodiment of the present application. Optionally, as shown in FIG. 2, in the repeating unit F, the third sub-opening K13 is located on a side of the second sub-opening K12 away from the first sub-opening K11 along the first direction X. This indicates that in the pixel unit, the third light-emitting structure 31c can be located on a side of the second light-emitting structure 31b away from the first sub-opening K11 along the first direction X. Or, as shown in FIG. 8, the third sub-opening K13 is located on the same side of the first sub-opening K11 and the second sub-opening K12 along a second direction Y. The first direction X and the second direction Y intersect. This indicates that in the pixel unit, the third light-emitting structure 31c can be located on the same side of the first light-emitting structure 31a and the second light-emitting structure 31b along the second direction Y. Optionally, the first direction X, the second direction Y, and the thickness direction Z are perpendicular to each other.

In the embodiment of the present application, depending on actual needs, the conformal design of the second orthographic projection T2 and the first opening pattern K1 can be applied to the arrangement structures shown in FIG. 2 or FIG. 8. In other words, the conformal design of the second orthographic projection T2 and the first opening pattern K1 can be applied to various types of pixel arrangement structures to meet the needs of different display panels 100 for reducing parasitic capacitance, and has strong flexibility and applicability.

In some embodiments, as shown in FIGS. 2, 3, and 8, the first opening pattern K1 includes a first edge R1 parallel to the first direction X and a second edge R2 parallel to the second direction Y. The second orthographic projection T2 includes a third edge R3 parallel to the first direction X and a fourth edge R4 parallel to the second direction Y. The first direction X and the second direction Y intersect. Here, the first straight edge B1 is one of the third edge R3 and the fourth edge R4, and the second straight edge B2 is one of the first edge R1 and the second edge R2.

For the above two types of pixel arrangements, the first opening pattern K1 can include a first edge R1 and a second edge R2. Both the first edge R1 and the second edge R2 are straight edges of the first opening pattern K1, but their corresponding extension directions are different. The first edge R1 extends along the first direction X, and the second edge R2 extends along the second direction Y.

The third edge R3 is a straight structure in the second orthographic projection T2 corresponding to the first edge R1. The fourth edge R4 is a straight structure in the second orthographic projection T2 corresponding to the second edge R2. The provision of the third edge R3 and the fourth edge R4 allows at least a part of the structure of the second orthographic projection T2 to be conformal with the first opening pattern K1, which helps to reduce the area size of the second orthographic projection T2 and reduce the parasitic capacitance between the first electrode 21 and the isolation structure 40.

Based on the foregoing, due to the presence of the isolation structure 40, the second electrode layer 50 can include a plurality of second electrodes 51 disposed corresponding to the plurality of isolation openings 41. On this basis, to meet display needs, the plurality of second electrodes 51 need to be scanned and transmitted sequentially in a specific straight-line direction to meet the transmission needs of the corresponding power signals.

On this basis, depending on actual needs, the first direction X can be the scanning direction of the plurality of second electrodes 51. Thus, the first edge R1 is a straight structure parallel to the scanning direction of the plurality of second electrodes 51. In this design, the first edge R1 can improve the signal transmission efficiency and accuracy of the plurality of second electrodes 51, thereby improving the display reliability of the display panel 100. Similarly, in other cases, the second direction Y can be the scanning direction of the plurality of second electrodes 51. Thus, the second edge R2 is a straight structure parallel to the scanning direction of the plurality of second electrodes 51. In this design, the second edge R2 can improve the signal transmission efficiency and accuracy of the plurality of second electrodes 51, thereby improving the display reliability of the display panel 100.

It should be noted that the first edge R1 and the second edge R2 are usually arranged alternately around the center of the first opening pattern K1. For the first edge R1 and the second edge R2 which are the closest to each other, they can be directly connected, or other straight or curved structures can be provided between them, which is not limited in the embodiment of the present application.

In some embodiments, the first opening pattern K1 further includes a first arc edge B4 connecting the first edge R1 and the second edge R2. The second orthographic projection T2 further includes a second arc edge B5 connecting the third edge R3 and the fourth edge R4.

In the embodiment of the present application, considering that the sixth orthographic projection of the light-emitting structure 31 can include rounded corner structures, the morphologies of the isolation structure 40 and the first electrode 21 are adjusted, so that the first opening pattern K1 includes the first arc edge B4 corresponding to the rounded corner structure and connecting the first edge R1 and the second edge R2, and the second orthographic projection T2 includes the second arc edge B5 corresponding to the rounded corner structure and connecting the third edge R3 and the fourth edge R4. This allows the shapes of the isolation opening 41 and the first electrode 21 to better match the shape of the light-emitting structure 31, thereby improving the light-emitting effect of the light-emitting structure 31 and helping to reduce the parasitic capacitance between the first electrode 21 and the isolation structure 40.

In some embodiments, referring to FIG. 9, the plurality of first opening patterns K1 include a first sub-opening K11, a second sub-opening K12, and a third sub-opening K13. The first sub-opening K11, the second sub-opening K12, and the third sub-opening K13 respectively correspond to light-emitting structures 31 of different colors. The centers of at least two first sub-openings K11 and the centers of at least two second sub-openings K12 form a first virtual polygon N1. The centers of the first sub-openings K11 are located at first vertexes of the first virtual polygon N1. The centers of the second sub-openings K12 are located at second vertexes of the first virtual polygon N1. The first vertices and the second vertices are alternately arranged in the first virtual polygon N1. The third sub-opening K13 is located inside the first virtual polygon N1.

The centers of at least four third sub-openings K13 form a second virtual polygon N2. The centers of a third sub-openings K13 are located at vertexes of the second virtual polygon N2. The first sub-opening K11 or the second sub-opening K12 is located inside the second virtual polygon N2.

The plurality of first opening patterns K1 can be arranged not only in the manner shown in FIGS. 2 and 8 but also in the manner shown in FIG. 9. In the arrangement of FIG. 9, the centers of at least two first sub-openings K11 and the centers of at least two second sub-openings K12 form the first virtual polygon N1. The “center” mentioned here refers to the geometric center of the corresponding structural pattern. The “first virtual polygon N1” is a virtual polygon formed by sequentially connecting the centers of at least two first sub-openings K11 and two second sub-openings K12. Here, the first virtual polygon N1 can be a quadrilateral, a hexagon, an octagon, etc. Further, under a condition that the first virtual polygon N1 is a quadrilateral, the quadrilateral can be a rectangular structure such as a rectangle or a square, or other parallelograms besides the rectangle, or a trapezoidal structure, which is not limited in the embodiment of the present application.

The third sub-opening K13 is located inside the first virtual polygon N1. The center of the third sub-opening K13 can coincide with the center of the first virtual polygon N1, or they can be offset from each other, which is not limited in the embodiment of the present application. Moreover, for adjacent two first virtual polygons N1, they can share the center of one first sub-opening K11 and the center of one second sub-opening K12.

In addition to the first virtual polygon N1, the centers of at least four third sub-opening K13 patterns can also form a second virtual polygon N2. The “second virtual polygon N2” mentioned here is a virtual quadrilateral formed by sequentially connecting the centers of four third sub-openings K13. Here, the second virtual polygon N2 can be a quadrilateral, a hexagon, an octagon, etc. Further, under a condition that the second virtual polygon N2 is a quadrilateral, the quadrilateral is a rectangular structure such as a rectangle or a square, or other parallelograms besides the rectangle, or a trapezoidal structure, which is not limited in the embodiment of the present application.

The first sub-opening K11 or the second sub-opening K12 is located inside the second virtual polygon N2. For adjacent two second virtual polygons N2, one second virtual polygon N2 contains the first sub-opening K11, and the other second virtual polygon N2 contains the second sub-opening K12. Here, in a single second virtual polygon N2 containing the first sub-opening K11, the center of the first sub-opening K11 can coincide with the center of the second virtual polygon N2, or they can be offset from each other. Similarly, in a single second virtual polygon N2 containing the second sub-opening K12, the center of the second sub-opening K12 can coincide with the center of the second virtual polygon N2, or they can be offset from each other, which is not limited in the embodiment of the present application.

Considering that the arrangement of the plurality of different first opening patterns K1 usually corresponds to the arrangement of the corresponding plurality of light-emitting structures 31, optionally, the plurality of light-emitting structures 31 include a first light-emitting structure 31a, a second light-emitting structure 31b, and a third light-emitting structure 31c. The first light-emitting structure 31a, the second light-emitting structure 31b, and the third light-emitting structure 31c correspond to the first sub-opening K11, the second sub-opening K12, and the third sub-opening K13, respectively. The centers of at least two first light-emitting structures 31a and the centers of at least two second light-emitting structures 31b form a third virtual polygon. The centers of the first light-emitting structures 31a are located at third vertexes of the third virtual polygon. The centers of the second light-emitting structures 31b are located at fourth vertexes of the third virtual polygon. The third vertices and the fourth vertices are alternately arranged in the third virtual polygon. The third light-emitting structure 31c is located inside the third virtual polygon.

The centers of at least four third light-emitting structures 31c form a fourth virtual polygon. The centers of the third light-emitting structures 31c are located at vertexes of the fourth virtual polygon. The first light-emitting structure 31a or the second light-emitting structure 31b is located inside the fourth virtual polygon.

In the embodiment of the present application, depending on actual needs, the conformal design of the second orthographic projection T2 and the first opening pattern K1 can also be applied to the arrangement structure shown in FIG. 8. In other words, the conformal design of the second orthographic projection T2 and the first opening pattern K1 can be applied to various types of pixel arrangement structures to meet the needs of different display panels 100 for reducing parasitic capacitance, and has strong flexibility and applicability.

In some embodiments, the center of the third sub-opening K13 coincides with the center of the first virtual polygon N1; or, in the first virtual polygon N1, the center of the third sub-opening K13 is at the same distance from the centers of at least two second sub-openings K12, and the center of the third sub-opening K13 is at the same distance from the centers of at least two first sub-openings K11.

Considering that the relative positional relationship of the plurality of light-emitting structures 31 usually corresponds to the positional relationship of the plurality of first opening patterns K1, in the embodiment of the present application, the center of the third light-emitting structure 31c can coincide with the center of the third virtual polygon; or, in the third virtual polygon, the center of the third light-emitting structure 31c is at the same distance from the centers of at least two second light-emitting structures 31b, and the center of the third light-emitting structure 31c is at the same distance from the centers of at least two first light-emitting structures 31a.

This design can reduce the risk of the distance between a single third light-emitting structure 31c and an adjacent first light-emitting structure 31a being too small or too large, and can also reduce the risk of the distance between a single third light-emitting structure 31c and an adjacent second light-emitting structure 31b being too small or too large, thereby helping to improve the display performance of the display panel 100.

In some embodiments, as shown in FIGS. 9 and 10, the first opening pattern K1 includes a fifth edge R5 extending along a third direction and a sixth edge R6 extending along a fourth direction. The fifth edge R5 and the sixth edge R6 are alternately arranged. The second orthographic projection T2 includes a seventh edge R7 extending along the third direction and an eighth edge R8 extending along the fourth direction. The seventh edge R7 and the eighth edge R8 are alternately arranged. The plurality of third sub-openings K13 are arranged in an array along the first direction X and the second direction Y. The first direction X, the second direction Y, the third direction, and the fourth direction intersect each other.

Referring to the figure, in this arrangement, the first direction X and the second direction Y correspond to the two arrangement directions of the plurality of third sub-openings K13. For example, for a rectangular display panel 100, the first direction X and the second direction Y can be the length and width directions of the display panel 100, respectively. Further optionally, the display panel 100 further includes a scan line. One of the first direction X and the second direction Y is parallel to the scan line, and the other is perpendicular to the scan line.

For the third direction and the fourth direction, both directions intersect the first direction X and the second direction Y, and they intersect each other. Optionally, the angle between the third direction and the first direction X can be one of 30°, 45°, or 60°. The angle between the fourth direction and the first direction X can also be one of 30°, 45°, or 60°.

Considering that in this arrangement, the sixth orthographic projection of the light-emitting structure 31 usually includes straight structures extending along the third direction and straight structures extending along the fourth direction, thus, the morphologies of the isolation structure 40 and the second electrode 51 are adjusted in the embodiment of the present application, so that the first opening pattern K1 includes a fifth edge R5 extending along the third direction and a sixth edge R6 extending along the fourth direction. The fifth edge R5 and the sixth edge R6 are alternately arranged. The second orthographic projection T2 includes a seventh edge R7 extending along the third direction and an eighth edge R8 extending along the fourth direction. The seventh edge R7 and the eighth edge R8 are alternately arranged.

In this design, the second orthographic projection T2 can achieve a conformal setting with the first opening pattern K1 through the seventh edge R7 and the eighth edge R8, thereby reducing the overlapping area between the isolation structure 40 and the first electrode 21 and reducing parasitic capacitance. At the same time, the morphologies of the second orthographic projection T2 and the first opening pattern K1 can better match the sixth orthographic projection, thereby improving the control accuracy of the first electrode 21 over the light-emitting structure 31 and the positional reliability of the light-emitting structure 31 relative to the isolation opening 41, and improving the light-emitting effect of the display panel 100.

In some embodiments, as shown in FIGS. 9 and 10, the second straight edge B2 extends along the first direction X. Two fifth edges R5, two second straight edges B2, and two sixth edges R6 are connected end to end in sequence. The first straight edge B1 extends along the second direction Y. Two seventh edges R7, two first straight edges B1, and two eighth edges R8 are connected end to end in sequence.

In the embodiment of the present application, the morphology of the isolation structure 40 is adaptively adjusted, so that the first opening pattern K1 includes the second straight edge B2. The design of the second straight edge B2 allows the second electrode 51 to contact the isolation structure 40 at the position corresponding to the second straight edge B2, thereby improving the connection effect between the second electrode 51 and the isolation structure 40, and enhancing the transmission reliability of the corresponding signal between the isolation structure 40 and the second electrode 51.

Further, the morphology of the first electrode 21 is also adjusted in the embodiment of the present application, so that the fifth orthographic projection T5 includes the first straight edge B1, and the second straight edge B2 is parallel to the first straight edge B1. This helps to improve the conformal effect between the first opening pattern K1 and the fifth orthographic projection T5, thereby helping to reduce the parasitic capacitance between the first electrode 21 and the isolation structure 40.

In a third Aspect, referring to FIG. 8, an embodiment of the present application provides a display panel 100. The display panel 100 includes a substrate 10, an isolation structure 40, and a light-emitting functional layer 30. The isolation structure 40 is disposed on a side of the substrate 10 and is provided with a plurality of isolation openings 41. The light-emitting functional layer 30 is disposed on a side of the substrate 10 and includes a light-emitting structure 31 at least partially located within an isolation opening 41.

The isolation structure 40 has a first orthographic projection T1 on the substrate 10. The first orthographic projection T1 defines a plurality of first opening patterns K1. The plurality of first opening patterns K1 include a first sub-opening K11, a second sub-opening K12, and a third sub-opening K13. The first sub-opening K11, the second sub-opening K12, and the third sub-opening K13 respectively correspond to light-emitting structures 31 of different colors. The centers of at least two first sub-openings K11 and the centers of at least two second sub-openings K12 form a first virtual polygon N1. The centers of the first sub-openings K11 are located at first vertexes of the first virtual polygon N1. The centers of the second sub-openings K12 are located at second vertexes of the first virtual polygon N1. The first vertices and the second vertices are alternately arranged in the first virtual polygon N1. The third sub-opening K13 is located inside the first virtual polygon N1.

The plurality of first opening patterns K1 can be arranged in the manner shown in FIG. 9. In this arrangement, the centers of at least two first sub-openings K11 and the centers of at least two second sub-openings K12 form the first virtual polygon N1. The “center” mentioned here refers to the geometric center of the corresponding structural pattern. The “first virtual polygon N1” is a virtual polygon formed by sequentially connecting the centers of at least two first sub-openings K11 and two second sub-openings K12. Here, the first virtual polygon N1 can be a quadrilateral, a hexagon, an octagon, etc. Further, under a condition that the first virtual polygon N1 is a quadrilateral, the quadrilateral can be a rectangular structure such as a rectangle or a square, or other parallelograms besides the rectangle, or a trapezoidal structure, which is not limited in the embodiment of the present application.

The third sub-opening K13 is located inside the first virtual polygon N1. The center of the third sub-opening K13 can coincide with the center of the first virtual polygon N1, or they can be offset from each other, which is not limited in the embodiment of the present application. Moreover, for adjacent two first virtual polygons N1, they can share the center of one first sub-opening K11 and the center of one second sub-opening K12.

Considering that the arrangement of the plurality of different first opening patterns K1 usually corresponds to the arrangement of the corresponding plurality of light-emitting structures 31, optionally, the plurality of light-emitting structures 31 include a first light-emitting structure 31a, a second light-emitting structure 31b, and a third light-emitting structure 31c. The first light-emitting structure 31a, the second light-emitting structure 31b, and the third light-emitting structure 31c correspond to the first sub-opening K11, the second sub-opening K12, and the third sub-opening K13, respectively. The centers of at least two first light-emitting structures 31a and the centers of at least two second light-emitting structures 31b form a third virtual polygon. The centers of the first light-emitting structures 31a are located at third vertexes of the third virtual polygon. The centers of the second light-emitting structures 31b are located at fourth vertexes of the third virtual polygon. The third vertices and the fourth vertices are alternately arranged in the third virtual polygon. The third light-emitting structure 31c is located inside the third virtual polygon.

In some embodiments, the center of the third sub-opening K13 coincides with the center of the first virtual polygon N1; or in other embodiments, in the first virtual polygon N1, the center of the third sub-opening K13 is at the same distance from the centers of at least two second sub-openings K12, and the center of the third sub-opening K13 is at the same distance from the centers of at least two first sub-openings K11.

Considering that the relative positional relationship of the plurality of light-emitting structures 31 usually corresponds to the positional relationship of the plurality of first opening patterns K1, in the embodiment of the present application, the center of the third light-emitting structure 31c can coincide with the center of the third virtual polygon; or, in the third virtual polygon, the center of the third light-emitting structure 31c is at the same distance from the centers of at least two second light-emitting structures 31b, and the center of the third light-emitting structure 31c is at the same distance from the centers of at least two first light-emitting structures 31a.

This design can reduce the risk of the distance between a single third light-emitting structure 31c and an adjacent first light-emitting structure 31a being too small or too large, and can also reduce the risk of the distance between a single third light-emitting structure 31c and an adjacent second light-emitting structure 31b being too small or too large, thereby helping to improve the display performance of the display panel 100.

In some embodiments, the centers of at least four third sub-openings K13 form a second virtual polygon N2. The centers of the third sub-openings K13 are located at vertexes of the second virtual polygon N2. The first sub-opening K11 or the second sub-opening K12 is located inside the second virtual polygon N2.

In addition to the first virtual polygon N1, the centers of at least four third sub-opening K13 patterns can also form a second virtual polygon N2. The “second virtual polygon N2” mentioned here is a virtual quadrilateral formed by sequentially connecting the centers of four third sub-openings K13. Here, the second virtual polygon N2 can be a quadrilateral, a hexagon, an octagon, etc. Further, under a condition that the second virtual polygon N2 is a quadrilateral, the quadrilateral is a rectangular structure such as a rectangle or a square, or other parallelograms besides the rectangle, or a trapezoidal structure, which is not limited in the embodiment of the present application.

The first sub-opening K11 or the second sub-opening K12 is located inside the second virtual polygon N2. For adjacent two second virtual polygons N2, one second virtual polygon N2 contains the first sub-opening K11, and the other second virtual polygon N2 contains the second sub-opening K12. Here, in a single second virtual polygon N2 containing the first sub-opening K11, the center of the first sub-opening K11 can coincide with the center of the second virtual polygon N2, or they can be offset from each other. Similarly, in a single second virtual polygon N2 containing the second sub-opening K12, the center of the second sub-opening K12 can coincide with the center of the second virtual polygon N2, or they can be offset from each other, which is not limited in the embodiment of the present application.

Considering that the arrangement of the plurality of different first opening patterns K1 usually corresponds to the arrangement of the corresponding plurality of light-emitting structures 31, optionally, the centers of at least four third light-emitting structures 31c form the fourth virtual polygon. The centers of the third light-emitting structures 31c are located at vertexes of the fourth virtual polygon. The first light-emitting structure 31a or the second light-emitting structure 31b is located inside the fourth virtual polygon.

Although the embodiments disclosed in the present application are described as above, the described content is only embodiments for facilitating the understanding of the present application, and is not intended to limit the present application. Any person skilled in the art to which the present application belongs may make any modifications and changes in the form and details of implementation without departing from the spirit and scope disclosed in the present application. However, the protection scope of the present application shall be subject to the scope defined by the appended claims.

The above are only specific embodiments of the present application. Those skilled in the art can clearly understand that, for the convenience and brevity of description, the above descriptions of other connection methods, replacements, etc., can be referred to the corresponding processes in the foregoing method embodiments, and are not repeated here. It should be understood that the protection scope of the present application is not limited thereto. Any person skilled in the art can easily think of various equivalent modifications or replacements within the technical scope disclosed in the present application, and these modifications or replacements shall fall within the protection scope of the present application.

What is claimed is:

1. A display panel, comprising:
a substrate;
a first electrode layer disposed on a side of the substrate, the first electrode layer comprising a plurality of first electrodes spaced apart;
an isolation structure disposed on a side of the substrate, the isolation structure being provided with a plurality of isolation openings, an orthographic projection of a first electrode on the substrate overlapping an orthographic projection of an isolation opening on the substrate;
a light-emitting functional layer disposed on a side of the first electrode layer away from the substrate, the light-emitting functional layer comprising a light-emitting structure disposed corresponding to the first electrode;
wherein the isolation structure has a first orthographic projection on the substrate, the first orthographic projection defines a plurality of first opening patterns, the first electrode has a second orthographic projection on the substrate, a first opening pattern overlaps the second orthographic projection, and at least a part of a graphic outer contour shape of the second orthographic projection is the same as an outer contour shape of the first opening pattern.

2. The display panel according to claim 1, wherein the isolation structure comprises a first isolation portion and a second isolation portion located on a side of the first isolation portion away from the substrate, an orthographic projection of the first isolation portion on the substrate is located within an orthographic projection of the second isolation portion on the substrate;
the first isolation portion has a third orthographic projection on the substrate, the third orthographic projection defines a plurality of second opening patterns, and at least a part of the graphic outer contour shape of the second orthographic projection is the same as an outer contour shape of a second opening pattern;
the second isolation portion has a fourth orthographic projection on the substrate, the fourth orthographic projection defines a plurality of third opening patterns, and at least a part of the graphic outer contour shape of the second orthographic projection being the same as an outer contour shape of a third opening pattern.

3. The display panel according to claim 2, wherein overlapping widths of a plurality of different regions of the second orthographic projection of a same first electrode with the third orthographic projection are the same; and,
the light-emitting functional layer comprises a plurality of first light-emitting structures for emitting light of a first color, overlapping widths of second orthographic projections of the first electrodes corresponding to different first light-emitting structures with the third orthographic projection are the same; and,
the light-emitting functional layer comprises a first light-emitting structure for emitting light of a first color and a second light-emitting structure for emitting light of a second color, an overlapping width of the second orthographic projection corresponding to the first light-emitting structure with the third orthographic projection is different from an overlapping width of the second orthographic projection corresponding to the second light-emitting structure with the third orthographic projection.

4. The display panel according to claim 2, wherein overlapping widths of a plurality of different regions of the second orthographic projection of a same first electrode with the fourth orthographic projection are the same; and,
the light-emitting structure has a sixth orthographic projection on the substrate, the light-emitting functional layer comprises a plurality of first light-emitting structures for emitting light of a first color, overlapping widths of sixth orthographic projections of different first light-emitting structures with the fourth orthographic projection are the same; and,
the light-emitting functional layer comprises a plurality of first light-emitting structures for emitting light of a first color, overlapping widths of second orthographic projections of the first electrodes corresponding to different first light-emitting structures with the fourth orthographic projection are the same; and,
the light-emitting functional layer comprises a first light-emitting structure for emitting light of a first color and a second light-emitting structure for emitting light of a second color, an overlapping width of the second orthographic projection of the first electrode corresponding to the first light-emitting structure with the fourth orthographic projection is the same as an overlapping width of the second orthographic projection of the first electrode corresponding to the second light-emitting structure with the fourth orthographic projection.

5. The display panel according to claim 1, wherein the first electrode comprises a body portion and a connection portion connected to the body portion, the substrate comprises a pixel circuit, the body portion is electrically connected to the pixel circuit through the connection portion;
the body portion has a fifth orthographic projection on the substrate, an outer contour shape of the fifth orthographic projection is the same as the outer contour shape of the first opening pattern.

6. The display panel according to claim 5, wherein the fifth orthographic projection comprises a first straight edge, the first opening pattern comprises a second straight edge, the first straight edge is parallel to the second straight edge.

7. The display panel according to claim 1, wherein the light-emitting structure has a sixth orthographic projection on the substrate, an outer contour shape of the sixth orthographic projection is the same as an outer contour shape of a corresponding first opening pattern; and,
the sixth orthographic projection comprises a third straight edge, the first opening pattern comprises a second straight edge, the third straight edge is parallel to the second straight edge.

8. The display panel according to claim 1, wherein the display panel further comprises a second electrode layer disposed on a side of the light-emitting functional layer away from the substrate, the second electrode layer comprises a plurality of second electrodes disposed in the plurality of isolation openings;
a second electrode has a seventh orthographic projection on the substrate, an outer contour shape of the seventh orthographic projection is the same as an outer contour shape of a corresponding first opening pattern; and,
the seventh orthographic projection comprises a fourth straight edge, the first opening pattern comprises a second straight edge, the fourth straight edge is parallel to the second straight edge.

9. The display panel according to claim 1, wherein the display panel further comprises a pixel definition layer located on a side of the isolation structure facing the substrate, the pixel definition layer comprises a pixel definition portion and a pixel opening enclosed and formed by the pixel definition portion;
an outer contour shape of an orthographic projection of the pixel opening on the substrate is the same as the outer contour shape of the first opening pattern; and,
the light-emitting structure has a sixth orthographic projection on the substrate, an outer contour shape of the sixth orthographic projection is the same as an outer contour shape of an orthographic projection of a corresponding pixel opening on the substrate.

10. The display panel according to claim 1, wherein the first opening pattern comprises a plurality of straight edges and a first arc edge, adjacent two straight edges of the first opening pattern are connected by the first arc edge;
the second orthographic projection comprises a plurality of straight edges and a second arc edge, adjacent two straight edges of the second orthographic projection are connected by the second arc edge;
for a same light-emitting structure, a radius of curvature of the second arc edge corresponding to the light-emitting structure is the same as or different from a radius of curvature of the first arc edge corresponding to the light-emitting structure; and,
the light-emitting functional layer comprises a first light-emitting structure and a second light-emitting structure with different light-emitting colors, a radius of curvature of the first arc edge of the first opening pattern corresponding to the first light-emitting structure is different from a radius of curvature of the first arc edge of the first opening pattern corresponding to the second light-emitting structure.

11. The display panel according to claim 1, wherein the plurality of first opening patterns comprise a first sub-opening, a second sub-opening, and a third sub-opening, the first sub-opening, the second sub-opening, and the third sub-opening respectively correspond to light-emitting structures of different colors;
the plurality of first opening patterns constitute a repeating unit, a plurality of repeating units are repeatedly arranged, the repeating unit comprises at least one first sub-opening, at least one second sub-opening, and at least one third sub-opening, and the first sub-opening and the second sub-opening are arranged side by side in a first direction.

12. The display panel according to claim 11, wherein in the repeating unit, the third sub-opening is located on a side of the second sub-opening away from the first sub-opening along the first direction; or, the third sub-opening is located on a same side of the first sub-opening and the second sub-opening along a second direction, the first direction and the second direction intersect;
the first opening pattern comprises a first edge parallel to the first direction and a second edge parallel to the second direction, the second orthographic projection comprises a third edge parallel to the first direction and a fourth edge parallel to the second direction, the first direction and the second direction intersect;
the first opening pattern further comprises a first arc edge connecting the first edge and the second edge, the second orthographic projection further comprises a second arc edge connecting the third edge and the fourth edge.

13. The display panel according to claim 1, wherein the plurality of first opening patterns comprise a first sub-opening, a second sub-opening, and a third sub-opening, the first sub-opening, the second sub-opening, and the third sub-opening respectively correspond to light-emitting structures of different colors;
centers of at least two first sub-openings and centers of at least two second sub-openings form a first virtual polygon, the centers of the first sub-openings are located at first vertexes of the first virtual polygon, the centers of the second sub-openings are located at second vertexes of the first virtual polygon, the first vertices and the second vertices are alternately arranged in the first virtual polygon, the third sub-opening is located inside the first virtual polygon;
centers of at least four third sub-openings form a second virtual polygon, the centers of the third sub-openings are located at vertexes of the second virtual polygon, the first sub-opening or the second sub-opening is located inside the second virtual polygon.

14. The display panel according to claim 13, wherein a center of the third sub-opening coincides with a center of the first virtual polygon; or,
in the first virtual polygon, the center of the third sub-opening is at the same distance from the centers of at least two second sub-openings, and the center of the third sub-opening is at the same distance from the centers of at least two first sub-openings.

15. The display panel according to claim 13, wherein the first opening pattern comprises a fifth edge extending along a third direction and a sixth edge extending along a fourth direction, the fifth edge and the sixth edge are alternately arranged, the second orthographic projection comprises a seventh edge extending along the third direction and an eighth edge extending along the fourth direction, the seventh edge and the eighth edge are alternately arranged;
wherein a plurality of third sub-openings are arranged in an array along a first direction and a second direction, the first direction, the second direction, the third direction, and the fourth direction intersect each other;
the first opening pattern further comprises a first connecting edge extending along the first direction, two fifth edges, two first connecting edges, and two sixth edges are connected end to end in sequence;
the second orthographic projection further comprises a second connecting edge extending along the first direction, two seventh edges, two second connecting edges, and two eighth edges are connected end to end in sequence.

16. The display panel according to claim 1, further comprising a first conductor layer disposed on a side of the first electrode layer facing the substrate, the first conductor layer comprising a first signal line;
wherein an orthographic projection of the first signal line on the substrate is located between adjacent second orthographic projections;
the first electrode comprises a body portion, the body portion has a fifth orthographic projection on the substrate, the orthographic projection of the first signal line on the substrate overlaps the fifth orthographic projection.

17. The display panel according to claim 16, wherein the fifth orthographic projection overlaps an orthographic projection of a single first signal line on the substrate, and the fifth orthographic projection is symmetric with respect to the orthographic projection of the single first signal line on the substrate; or,
the fifth orthographic projection overlaps orthographic projections of a plurality of first signal lines on the substrate, and the orthographic projections of the plurality of first signal lines overlapping the fifth orthographic projection on the substrate are symmetric with respect to a central axis of the fifth orthographic projection.

18. The display panel according to claim 1, further comprising a first encapsulation layer disposed on a side of the light-emitting functional layer away from the substrate, the first encapsulation layer comprising an encapsulation portion disposed corresponding to the isolation opening;
an outer contour shape of an orthographic projection of the encapsulation portion on the substrate is the same as the outer contour shape of the first opening pattern.

19. A display panel, comprising:
a substrate;
a first electrode layer disposed on a side of the substrate, the first electrode layer comprising a plurality of first electrodes spaced apart;
an isolation structure disposed on a side of the substrate, the isolation structure being provided with a plurality of isolation openings, an orthographic projection of a first electrode on the substrate overlapping an orthographic projection of an isolation opening on the substrate;
a light-emitting functional layer disposed on a side of the first electrode layer away from the substrate, the light-emitting functional layer comprising a light-emitting structure disposed corresponding to the first electrode;
wherein the isolation structure has a first orthographic projection on the substrate, the first orthographic projection defines a plurality of first opening patterns, the first electrode has a second orthographic projection on the substrate, the second orthographic projection comprises a first straight edge, a first opening pattern comprises a second straight edge, the first straight edge is parallel to the second straight edge.

20. The display panel according to claim 19, wherein at least a part of a graphic outer contour shape of the second orthographic projection is the same as an outer contour shape of the first opening pattern;
the isolation structure comprises a first isolation portion and a second isolation portion located on a side of the first isolation portion away from the substrate, the second isolation portion covers and extends beyond the first isolation portion;
the first isolation portion has a third orthographic projection on the substrate, the third orthographic projection defines a plurality of second opening patterns, and at least a part of the graphic outer contour shape of the second orthographic projection is the same as an outer contour shape of a second opening pattern.

21. The display panel according to claim 20, wherein overlapping widths of a plurality of different regions of the second orthographic projection of a same first electrode with the third orthographic projection are the same; and,
the light-emitting functional layer comprises a plurality of first light-emitting structures for emitting light of a first color, overlapping widths of second orthographic projections of the first electrodes corresponding to different first light-emitting structures with the third orthographic projection are the same; and
the light-emitting functional layer comprises a first light-emitting structure for emitting light of a first color and a second light-emitting structure for emitting light of a second color, an overlapping width of the second orthographic projection of the first electrode corresponding to the first light-emitting structure with the third orthographic projection is different from an overlapping width of the second orthographic projection of the first electrode corresponding to the second light-emitting structure with the third orthographic projection.

22. The display panel according to claim 19, wherein the first electrode comprises a body portion and a connection portion connected to the body portion, the display panel further comprises a pixel circuit, the body portion is electrically connected to the pixel circuit through the connection portion;
the body portion has a fifth orthographic projection on the substrate, an outer contour shape of the fifth orthographic projection is the same as the outer contour shape of the first opening pattern;
the fifth orthographic projection comprises a first straight edge, the first opening pattern comprises a second straight edge, the first straight edge is parallel to the second straight edge.

23. The display panel according to claim 19, wherein the plurality of first opening patterns comprise a first sub-opening, a second sub-opening, and a third sub-opening, the first sub-opening, the second sub-opening, and the third sub-opening respectively correspond to light-emitting structures of different colors;
the plurality of first opening patterns constitute a repeating unit, a plurality of repeating units are repeatedly arranged, the repeating unit comprises at least one first sub-opening, at least one second sub-opening, and at least one third sub-opening, and the first sub-opening and the second sub-opening are arranged side by side in a first direction.

24. The display panel according to claim 23, wherein in the repeating unit, the third sub-opening is located on a side of the second sub-opening away from the first sub-opening along the first direction; or, the third sub-opening is located on a same side of the first sub-opening and the second sub-opening along a second direction, the first direction and the second direction intersect.

25. The display panel according to claim 23, wherein the first opening pattern comprises a first edge parallel to the first direction and a second edge parallel to the second direction, the second orthographic projection comprises a third edge parallel to the first direction and a fourth edge parallel to the second direction, the first direction and the second direction intersect;
wherein, the first straight edge is one of the third edge and the fourth edge, the second straight edge is one of the first edge and the second edge;
the first opening pattern further comprises a first arc edge connecting the first edge and the second edge, the second orthographic projection further comprises a second arc edge connecting the third edge and the fourth edge.

26. The display panel according to claim 19, wherein the plurality of first opening patterns comprise a first sub-opening, a second sub-opening, and a third sub-opening, the first sub-opening, the second sub-opening, and the third sub-opening respectively correspond to light-emitting structures of different colors;
centers of at least two first sub-openings and centers of at least two second sub-openings form a first virtual polygon, the centers of the first sub-openings are located at first vertexes of the first virtual polygon, the center of the second sub-openings are located at second vertexes of the first virtual polygon, the first vertices and the second vertices are alternately arranged in the first virtual polygon, the third sub-opening is located inside the first virtual polygon;
centers of at least four third sub-openings form a second virtual polygon, the centers of the third sub-openings are located at vertexes of the second virtual polygon, the first sub-opening or the second sub-opening is located inside the second virtual polygon.

27. The display panel according to claim 26, wherein the first opening pattern comprises a fifth edge extending along a third direction and a sixth edge extending along a fourth direction, the fifth edge and the sixth edge are alternately arranged, the second orthographic projection comprises a seventh edge extending along the third direction and an eighth edge extending along the fourth direction, the seventh edge and the eighth edge are alternately arranged;
wherein a plurality of third sub-openings are arranged in an array along a first direction and a second direction, the first direction, the second direction, the third direction, and the fourth direction intersect each other;
wherein the second straight edge extends along the first direction, two fifth edges, two second straight edges, and two sixth edges are connected end to end in sequence;
the first straight edge extends along the second direction, two seventh edges, two first straight edges, and two eighth edges are connected end to end in sequence.

28. A display panel, comprising:
a substrate;
an isolation structure disposed on a side of the substrate, the isolation structure being provided with a plurality of isolation openings;
a light-emitting functional layer disposed on a side of the substrate, the light-emitting functional layer comprising a light-emitting structure at least partially located within an isolation opening;
wherein the isolation structure has a first orthographic projection on the substrate, the first orthographic projection defines a plurality of first opening patterns, the plurality of first opening patterns comprise a first sub-opening, a second sub-opening, and a third sub-opening, the first sub-opening, the second sub-opening, and the third sub-opening respectively correspond to light-emitting structures of different colors;
centers of at least two first sub-openings and centers of at least two second sub-openings form a first virtual polygon, the centers of the first sub-openings are located at first vertexes of the first virtual polygon, the centers of the second sub-openings are located at second vertexes of the first virtual polygon, the first vertices and the second vertices are alternately arranged in the first virtual polygon, the third sub-opening is located inside the first virtual polygon.

29. The display panel according to claim 28, wherein a center of the third sub-opening coincides with a center of the first virtual polygon; and,
in the first virtual polygon, the center of the third sub-opening is at the same distance from the centers of at least two second sub-openings, and the center of the third sub-opening is at the same distance from the centers of at least two first sub-openings.

30. The display panel according to claim 28, wherein
centers of at least four third sub-openings form a second virtual polygon, the centers of the third sub-openings are located at vertexes of the second virtual polygon, the first sub-opening or the second sub-opening is located inside the second virtual polygon.
